(19) United States
(12) Patent Application Publication
(10) Pub. No.: US 2026/0215020 A1
(43) Pub. Date: Jul. 23, 2026

(54) IMAGE SENSOR

(71) Applicant: SAMSUNG ELECTRONICS CO., LTD., Suwon-si (KR)

(72) Inventor: Kook Tae Kim, Suwon-si (KR)

(73) Assignee: SAMSUNG ELECTRONICS CO., LTD., Suwon-si (KR)

(21) Appl. No.: 19/361,868

(22) Filed: Oct. 17, 2025

(30) Foreign Application Priority Data
Jan. 23, 2025 (KR) 10-2025-0010239

(51) Int. Cl. H10F 39/00

(52) U.S. Cl. CPC H10F 39/811; H10F 39/80373; H10F 39/807

(57) ABSTRACT

Provided is an image sensor including a substrate, a first pixel including a first floating diffusion region in the substrate, a second pixel including a second floating diffusion region in the substrate, a first pad including a first extension portion extending along a first surface of the first floating diffusion region and contacting the first floating diffusion region, a second extension portion extending into the substrate, and a first connection portion connecting the first extension portion and the second extension portion, a second pad including a third extension portion extending along a first surface of the second floating diffusion region and contacting the second floating diffusion region, a fourth extension portion extending into the substrate, and a second connection portion connecting the third extension portion and the fourth extension portion, and a connection pad between and contacting the first pad and the second pad.

### CROSS-REFERENCE TO RELATED APPLICATION

This application claims priority to Korean Patent Application No. 10-2025-0010239 filed on January 23, 2025 in the Korean Intellectual Property Office, the disclosure of which is incorporated herein in its entirety by reference.

### BACKGROUND

### Field

Embodiments of the present disclosure relate to an image sensor.

### Description of Related Art

An image senor is one of semiconductor devices that converts optical information into an electrical signal. The image sensor may include a charge-coupled device (CCD) based image sensor and a complementary metal-oxide semiconductor (CMOS) based image sensor.

The image sensor may be embodied in a form of a package. In this case, the package may be configured to have a structure that protects the image sensor and, at the same time, allows light to be incident on a photo receiving surface or a sensing area of the image sensor.

### SUMMARY

One or more embodiments provide an image sensor with improved reliability.

According to an aspect of one or more embodiments, there is provided an image sensor including a substrate, a first pixel including a first floating diffusion region in the substrate, a second pixel including a second floating diffusion region in the substrate, a first pad including a first extension portion extending along a first surface of the first floating diffusion region and contacting the first floating diffusion region, a second extension portion extending into the substrate, and a first connection portion connecting the first extension portion and the second extension portion to each other, a second pad including a third extension portion extending along a first surface of the second floating diffusion region and contacting the second floating diffusion region, a fourth extension portion extending into the substrate, and a second connection portion connecting the third extension portion and the fourth extension portion to each other, and a connection pad between the first pad and the second pad and in contact with the first pad and the second pad.

According to another aspect of one or more embodiments, there is provided an image sensor including a substrate, a first floating diffusion region, a second floating diffusion region, a third floating diffusion region, and a fourth floating diffusion region in the substrate, a first pad in contact with a first surface of the first floating diffusion region, a second pad in contact with a first surface of the second floating diffusion region, a third pad in contact with a first surface of the third floating diffusion region, a fourth pad in contact with a first surface of the fourth floating diffusion region, and a connection pad in contact with the first pad, the second pad, the third pad, and the fourth pad, wherein a level of an uppermost surface of the first pad, a level of an uppermost surface of the second pad, a level of an uppermost surface of the third pad, and a level of an uppermost surface of the fourth pad are different from a level of a first surface of the connection pad in the vertical direction.

According to still another aspect of one or more embodiments, there is provided an image sensor including a substrate, a first floating diffusion region, a second floating diffusion region, a third floating diffusion region, and a fourth floating diffusion region in the substrate, a first pad in contact with the first floating diffusion region, a second pad in contact with the second floating diffusion region, a third pad in contact with the third floating diffusion region, a fourth pad in contact with the fourth floating diffusion region, a connection pad contacting the first pad, the second pad, the third pad, and the fourth pad, a contact on the connection pad, and a transfer gate electrode at least partially in the substrate, wherein a level of an uppermost surface of the first pad, a level of an uppermost surface of the second pad, a level of an uppermost surface of the third pad, and a level of an uppermost surface of the fourth pad are different from a level of an upper surface of the connection pad and a level of a first surface of the transfer gate electrode in the vertical direction.

According to an aspect of one or more embodiments, there is provided a method of manufacturing an image sensor including forming a substrate, forming a first pixel including a first floating diffusion region in the substrate, forming a second pixel including a second floating diffusion region in the substrate, forming a first pad including a first extension portion extending along a first surface of the first floating diffusion region and contacting the first floating diffusion region, a second extension portion extending into the substrate, and a first connection portion connecting the first extension portion and the second extension portion to each other, forming a second pad including a third extension portion extending along a first surface of the second floating diffusion region and contacting the second floating diffusion region, a fourth extension portion extending into the substrate, and a second connection portion connecting the third extension portion and the fourth extension portion to each other; and forming a connection pad between the first pad and the second pad and contacting the first pad and the second pad.

### BRIEF DESCRIPTION OF DRAWINGS

The above and other aspects and features of the present disclosure will become more apparent by describing in detail illustrative embodiments thereof with reference to the attached drawings, in which:

FIG. 1 is an example circuit diagram for illustrating a pixel array of an image sensor according to one or more embodiments;

FIG. 2 is a plan view for illustrating a pixel array of an image sensor according to one or more embodiments;

FIG. 3 is a schematic cross-sectional view taken along a line A-A' of FIG. 2;

FIG. 4 is a schematic cross-sectional view taken along a line B-B' of FIG. 2;

FIGS. 5, 6, 7, 8, 9, 10, 11, 12, 13, 14, 15, 16, 17, and 18 are diagrams illustrating intermediate structures corresponding to intermediate steps of a method for manufacturing an image sensor according to one or more embodiments;

FIGS. 19 and 20 are further cross-sectional views for illustrating an image sensor according to one or more embodiments;

FIGS. 21, 22, 23, 24, 25, 26, 27, and 28 are diagrams illustrating intermediate structures corresponding to intermediate steps of a method for manufacturing an image sensor according to one or more embodiments.

FIGS. 29 and 30 are further cross-sectional views for illustrating an image sensor according to one or more embodiments;

FIG. 31 is a diagram illustrating an intermediate structure corresponding to an intermediate step of a method for manufacturing an image sensor according to one or more embodiments;

FIGS. 32 and 33 are further cross-sectional views for illustrating an image sensor according to one or more embodiments;

FIGS. 34 and 35 are diagrams illustrating intermediate structures corresponding to intermediate steps of a method for manufacturing an image sensor according to one or more embodiments;

FIGS. 36, 37, 38, 39, 40, and 41 are plan views for illustrating a pixel array of an image sensor according to one or more embodiments;

FIG. 42 is a plan view for illustrating a pixel array of an image sensor according to one or more embodiments;

FIG. 43 is a plan view for illustrating a pixel array of an image sensor according to one or more embodiments;

FIG. 44 is a schematic cross-sectional view taken along a line C-C' of FIG. 43; and

FIGS. 45 and 46 are various plan views for illustrating a pixel array of an image sensor according to one or more embodiments.

### DETAILS DESCRIPTIONS

Hereinafter, embodiments are described in detail with reference to the accompanying drawings. The same reference numerals denote the same elements in the drawings, and redundant descriptions on the same elements are omitted. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

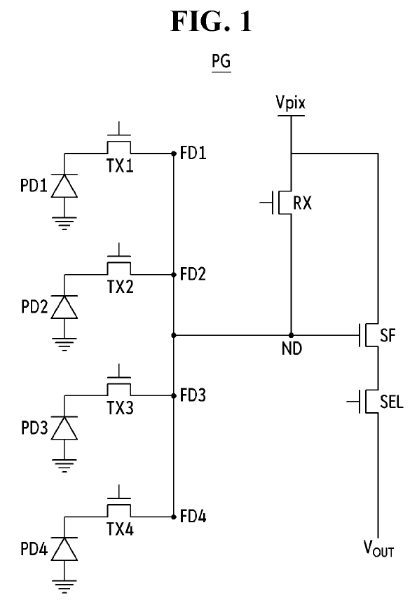

FIG. 1 is an example circuit diagram for illustrating a pixel array of an image sensor according to one or more embodiments.

Referring to FIG. 1, an image sensor according to one or more embodiments includes a pixel group PG.

The pixel group PG may include a first photodiode PD1, a second photodiode PD2, a third photodiode PD3, and a fourth photodiode PD4, a first transfer transistor TX1, a second transfer transistor TX2, a third transfer transistor TX3, and a fourth transfer transistor TX4, a first floating diffusion region FD1, a second floating diffusion region FD2, a third floating diffusion FD3, and a fourth floating diffusion region FD4, a reset transistor RX, a source follower transistor SF, and a selection transistor SEL.

Each of the first to fourth photodiodes PD1 to PD4 may generate electric charges in proportion to an amount of light incident thereto from the outside. For example, each of the first to fourth photodiodes PD1 to PD4 may include at least one of a photodiode, a photo transistor, a photo gate, a pinned photo diode (PPD), or a combination thereof. However, embodiments are not limited thereto.

The first to fourth transfer transistors TX1 to TX4 may be coupled to the first to fourth photodiodes PD1 to PD4, respectively. The first to fourth transfer transistors TX1 to TX4 may transfer charges generated and accumulated in the first to fourth photodiodes PD1 to PD4 to the first to fourth floating diffusion regions FD1 to FD4, respectively. Each of the first to fourth floating diffusion regions FD1 to FD4 refers to an area for converting the charges into voltage and has parasitic capacitance such that the charges may be stored therein in an accumulated manner. Each of the first to fourth transfer transistors TX1 to TX4 may be embodied as a transistor driven by a predetermined bias (e.g., a transfer signal). For example, the first to fourth transfer transistors TX1 to TX4 may transfer the charges generated from the first to fourth photodiodes PD1 to PD4 to the first to fourth floating diffusion regions FD1 to FD4 based on the respective transfer signals, respectively.

In one or more embodiments, the first to fourth floating diffusion regions FD1 to FD4 may be commonly connected to a common node ND. For example, the pixel group PG may include the common node ND sharing the first to fourth floating diffusion regions FD1 to FD4 with each other.

The source follower transistor SF may amplify a change in electrical potential of the common node ND and output the amplified change to an output line V_{OUT}. When the source follower transistor SF is turned on, a predetermined electrical potential, for example, a power voltage Vₚᵢₓ provided to a drain of the source follower transistor SF may be transferred to a drain area of the selection transistor SEL.

The selection transistor SEL may select a pixel group PG to be read on a row basis. The selection transistor SEL may be embodied as a transistor driven by a selection line applying a predetermined bias (e.g., a row select signal).

The reset transistor RX may periodically reset the first to fourth floating diffusion regions FD1 to FD4. The reset transistor RX may be embodied as a transistor driven by a reset line that applies a predetermined bias (e.g., a reset signal). When the reset transistor RX is turned on based on the reset signal, a predetermined electrical potential, for example, the power voltage Vₚᵢₓ provided to a drain of the reset transistor RX may be transferred to the common node ND, such that the first to fourth floating diffusion regions FD1 to FD4 may be reset.

The pixel group PG may further include a dual conversion gain transistor, etc. The pixel group PG may include a plurality of selection transistors SEL, a plurality of reset transistors RX, and/or a plurality of source follower transistors SF.

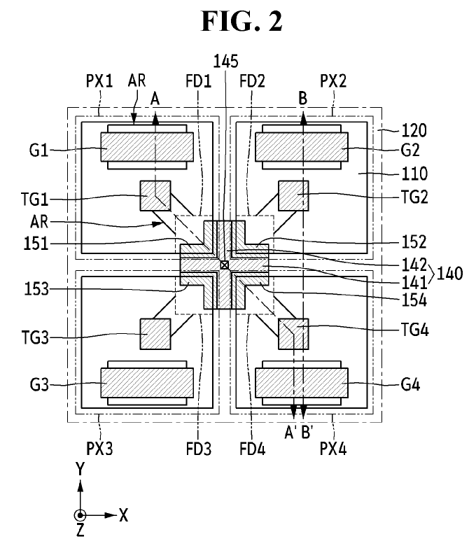

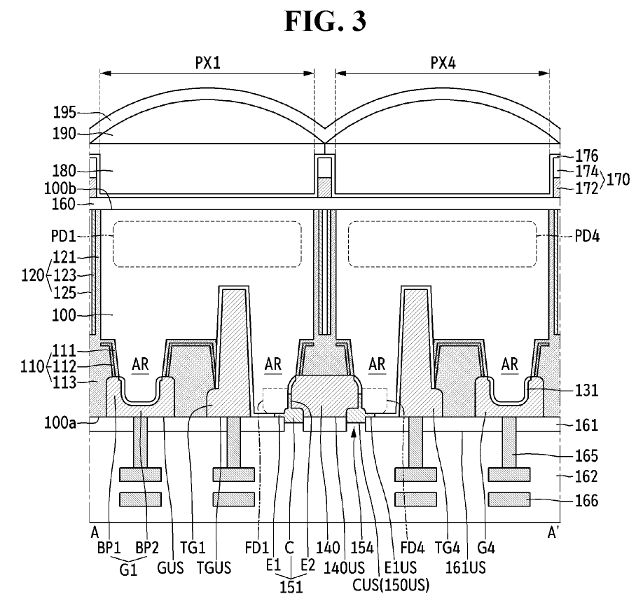

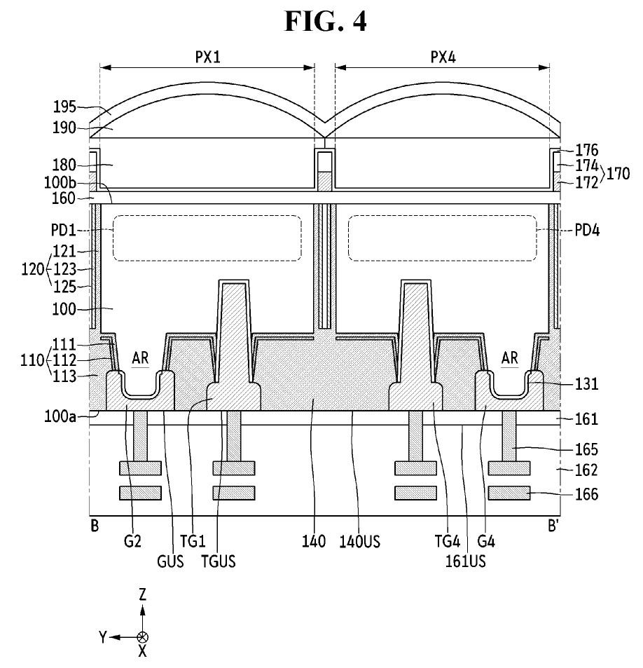

FIG. 2 is a plan view for illustrating a pixel array of an image sensor according to one or more embodiments. FIG. 3 is a schematic cross-sectional view taken along a line A-A' of FIG. 2. FIG. 4 is a schematic cross-sectional view taken along a line B-B' of FIG. 2.

Referring to FIGS. 2 to 4, the image sensor according to one or more embodiments includes a substrate 100, first to fourth photodiodes PD1 to PD4, an shallow trench isolation pattern 110, a PD isolation pattern 120, first to fourth floating diffusion regions FD1 to FD4, first to fourth transfer gate electrodes TG1 to TG4, first to fourth gate electrodes G1 to G4, a connection pad 140, first to fourth pads 151 to 154, a surface insulating film 160, a grid 170, a color filter 180, and a microlens 190.

The substrate 100 may be a semiconductor substrate. For example, the substrate 100 may be made of bulk silicon or silicon-on-insulator (SOI). The substrate 100 may be a silicon substrate, or may include a material other than silicon, for example, silicon germanium, indium antimonide, lead telluride compound, indium arsenide, indium phosphide, gallium arsenide, or gallium antimonide. As another example, the substrate 100 may include a base substrate and an epitaxial layer on the base substrate.

The substrate 100 may include a first surface 100a and a second surface 100b opposite to each other in a third direction Z. Hereinafter, the first surface 100a may also be referred to as a front surface (front side) of the substrate 100, and the second surface 100b may also be referred to as a back surface (back side) or a rear surface of the substrate 100. In one or more embodiments, the second surface 100b of the substrate 100 may be a light-receiving surface on which light is incident. For example, the image sensor according to one or more embodiments may be a back-illuminated (BSI) image sensor.

Hereinafter, the upper surface, the lower surface, an upper side, and a lower side are defined based on a direction from the second surface 100b toward the first surface 100a. The upper surface may be referred to as the first surface.

In one or more embodiments, the substrate 100 may contain impurities of a first conductivity type. In embodiments to be described below, the first conductivity type is described as being a p-type. However, this is only an example, and the first conductivity type may be an n-type.

The image sensor may include a plurality of pixels PX1 to PX4. The plurality of pixels PX1 to PX4 may be two-dimensionally (e.g., in a matrix form) arranged along a horizontal plane (e.g., an XY plane including a first direction X and a second direction Y).

The plurality of pixels PX1 to PX4 may include a first pixel PX1, a second pixel PX2, a third pixel PX3, and a fourth pixel PX4 which are adjacent to each other. The second pixel PX2 may be adjacent to the first pixel PX1 in the first direction X. The fourth pixel PX4 may be adjacent to the third pixel PX3 in the first direction X. The first pixel PX1 may be adjacent to the third pixel PX3 in the second direction Y. The second pixel PX2 may be adjacent to the fourth pixel PX4 in the second direction Y. The second pixel PX2 may be adjacent to the third pixel PX3 in a diagonal direction between the first direction X and the second direction Y. The first to fourth pixels PX1 to PX4 may be arranged in two rows and two columns.

The first to fourth photodiodes PD1 to PD4 may be formed in the substrate 100. The first to fourth photodiodes PD1 to PD4 may be two-dimensionally (e.g., in the form of a matrix) arranged in the substrate 100. The first to fourth pixels PX1 to PX4 may include the first to fourth photodiodes PD1 to PD4, respectively. Each of the first to fourth photodiodes PD1 to PD4 may have a second conductivity type different from the first conductivity type.

An shallow trench isolation pattern 110 may be formed in the substrate 100. The shallow trench isolation pattern 110 may be adjacent to (or in contact with) the first surface 100a of the substrate 100. The shallow trench isolation pattern 110 may define an active area AR adjacent to the first surface 100a in each of the first to fourth pixels PX1 to PX4. For example, a shallow trench (hereinafter, also referred to as an element isolation trench) extending from the first surface 100a to define the active area AR may be formed in the substrate 100. The shallow trench isolation pattern 110 may fill at least a portion of the element isolation trench. A shape, size, number, and arrangement of the active areas AR in each of the first to fourth pixels PX1 to PX4 are only examples and are not limited to those as illustrated.

The shallow trench isolation pattern 110 may include an insulating material, for example, at least one of silicon oxide, silicon nitride, silicon oxynitride, or a combination thereof. However, embodiments are not limited thereto. The shallow trench isolation pattern 110 may be formed as a single film or a stack of multiple films.

In one or more embodiments, the shallow trench isolation pattern 110 may include a first element isolation film 111 including silicon oxide, a second element isolation film 112 including silicon nitride and disposed on the first element isolation film 111, and a third element isolation film 113 including silicon oxide and disposed on the second element isolation film 112.

A PD isolation pattern 120 may be formed in the substrate 100. The PD isolation pattern 120 may define an area in which each of the first to fourth pixels PX1 to PX4 is disposed in the substrate 100. For example, a deep trench (hereinafter, referred to as a pixel isolation trench) defining an area in which each of the first to fourth pixels PX1 to PX4 is disposed may be formed in the substrate 100. For example, the pixel isolation trench PT may be formed in a grid shape in a plan view (e.g., in the XY plane) to surround each of the first to fourth pixels PX1 to PX4. The PD isolation pattern 120 may fill at least a portion of the pixel isolation trench.

The PD isolation pattern 120 may prevent photocharges generated in a specific pixel (e.g., the first pixel PX1) from migrating to other pixels (e.g., the second to fourth pixels PX2 to PX4) adjacent thereto in a random drift manner. In addition, the PD isolation pattern 120 may prevent optical cross-talk in which light incident on a specific pixel (e.g., the first pixel PX1) is incident on other pixels (e.g., the second to fourth pixels PX2 to PX4) adjacent thereto.

In one or more embodiments, the PD isolation pattern 120 may include a liner insulating film 121, a gap-fill conductive film 123, and a buried film 125.

The liner insulating film 121 may be deposited on an inner wall of the substrate 100. The liner insulating film 121 may be interposed between the substrate 100 and the gap-fill conductive film 123. For example, the liner insulating film 121 may conformally extend along a profile of the inner wall of the substrate 100.

Each of the liner insulating film 121 and the buried film 125 may include an insulating material, for example, at least one of silicon oxide, silicon nitride, silicon oxynitride, or a combination thereof. However, embodiments are not limited thereto. Although the liner insulating film 121 is illustrated as a single film, embodiments are not limited thereto, and the liner insulating film 121 may be embodied as a stack of multi films.

The gap-fill conductive film 123 may be deposited on the liner insulating film 121. The gap-fill conductive film 123 may be interposed between the liner insulating film 121 and the buried film 125. The gap-fill conductive film 123 may conformally extend along the liner insulating film 121. The gap-fill conductive film 123 may be spaced apart from the first surface 100a and may be in contact with the second surface 100b.

The gap-fill conductive film 123 may include a conductive material, for example, at least one of an undoped silicon germanium film, an impurity-doped polysilicon film, an impurity-doped silicon germanium film, or a metal film. However, embodiments are not limited thereto. For example, the gap-fill conductive film 123 may include a polysilicon film doped with p-type impurities (e.g., boron (B)) or n-type impurities (e.g., phosphorus (P) or arsenic (As)).

In one or more embodiments, a negative bias voltage may be applied to the gap-fill conductive film 123. The gap-fill conductive film 127 may improve dark current characteristics of the image sensor by holding holes that may exist on the surface of the substrate 100 adjacent to the PD isolation pattern 120.

The buried film 125 may be deposited on the gap-fill conductive film 123. The buried film 125 may fill an area of the PD isolation pattern 120 remaining after the liner insulating film 121 and the gap-fill conductive film 123 fill the PD isolation pattern 120. The buried film 125 may be spaced apart from the first surface 100a and may be in contact with the second surface 100b. In one or more embodiments, a portion of the liner insulating film 121 may be interposed between the buried film 125 and the gap-fill conductive film 123 and the shallow trench isolation pattern 110.

In one or more embodiments, the buried film 125 may include an insulating material, for example, at least one of silicon oxide, silicon nitride, silicon oxynitride, or a combination thereof. However, embodiments are not limited thereto. Although the buried film 125 is shown as a single film, embodiments are not limited thereto, and the buried film 125 may be embodied as a stack of multi films.

Although it is illustrated that a boundary between the liner insulating film 121 and the buried film 125 is defined, this is only an example. In another example, the boundary between the liner insulating film 121 and the buried film 125 may not be defined. For example, when the liner insulating film 121 and the buried film 125 include the same material (e.g., silicon oxide film), the boundary between the liner insulating film 121 and the buried film 125 may not be defined. For example, when the first and third element isolation films 111 and 113 and the liner insulating film 121 include the same material (e.g., silicon oxide film), boundaries between the first and third element isolation films 111 and 113 and the liner insulating film 121 may not be defined. Although it is illustrated that the boundary between the shallow trench isolation pattern 110 and the liner insulating film 121 is not defined, this is only an example. In another example, the boundary between the shallow trench isolation pattern 110 and the liner insulating film 121 may be defined.

In one or more embodiments, a portion and an entirety of the buried film 125 may include a conductive material, for example, at least one of an undoped polysilicon film, an impurity-doped polysilicon film, an impurity-doped silicon germanium film, or a metal film. However, embodiments are not limited thereto. For example, the buried film 125 may include a polysilicon film doped with p-type impurities (e.g., boron (B)) or n-type impurities (e.g., phosphorus (P) and arsenic (As)). For example, after an undoped polysilicon film is formed on the gap-fill conductive film 123, the p-type impurities (e.g., boron (B)) or the n-type impurities (e.g., phosphorus (P) or arsenic (As)) of the gap-fill conductive film 123 may be diffused into the undoped polysilicon film to form the buried film 125 including the polysilicon film doped with the p-type impurities (e.g., boron (B)) or the n-type impurities (e.g., phosphorus (P) or arsenic (As).

The first to fourth pixels PX1 to PX4 may include the first to fourth floating diffusion regions FD1 to FD4, first to fourth transfer gate electrodes TG1 to TG4, and first to fourth gate electrodes G1 to G4, respectively.

The first to fourth floating diffusion regions FD1 to FD4 may be formed in the substrate 100. Each of the first to fourth floating diffusion regions FD1 to FD4 may be formed in the active area AR of each of the first to fourth pixels PX1 to PX4. Each of the first to fourth floating diffusion regions FD1 to FD4 may have the second conductivity type.

The first to fourth transfer gate electrodes TG1 to TG4 may be adjacent to the first to fourth floating diffusion regions FD1 to FD4, respectively. For example, each of the first to fourth transfer gate electrodes TG1 to TG4 may be disposed in each active area AR adjacent to each of the first to fourth floating diffusion regions FD1 to FD4. The shape, size, number, and arrangement of each of the first to fourth transfer gate electrodes TG1 to TG4 are only examples and are not limited to those as illustrated. The first to fourth transfer gate electrodes TG1 to TG4 may be provided as gates of the first to fourth transfer transistors TX1 to TX4 of FIG. 1, respectively.

In one or more embodiments, each of the first to fourth transfer gate electrodes TG1 to TG4 may be a vertical transfer gate electrode. For example, at least a portion of each of the first to fourth transfer gate electrodes TG1 to TG4 may extend into the substrate 100 toward each of the first to fourth photodiodes PD1 to PD4. The first to fourth transfer gate electrodes TG1 to TG4 may be adjacent to (or in contact with) the first surface 100a of the substrate 100 and may be spaced apart from the second surface 100b of the substrate 100.

In one or more embodiments, each of the first to fourth transfer gate electrodes TG1 to TG4 may be disposed in the substrate 100. Upper surfaces TGUS of the first to fourth transfer gate electrodes TG1 to TG4 may be adjacent to (or in contact with) the first surface 100a of the substrate 100.

For example, a portion of each of the first to fourth transfer gate electrodes TG1 to TG4 may be disposed in the shallow trench isolation pattern 110. Lower surfaces of the first to fourth transfer gate electrodes TG1 to TG4 positioned in the shallow trench isolation pattern 110 may be located at a higher vertical level than a vertical level of lower surfaces of the first to fourth transfer gate electrodes TG1 to TG4 positioned in the substrate 100 in the third direction Z.

Each of the first to fourth gate electrodes G1 to G4 may be disposed in the active area AR of each of the first to fourth pixels PX1 to PX4. The shape, size, number, and arrangement of each of the first to fourth gate electrodes G1 to G4 are only examples and are not limited to those as illustrated.

The first to fourth gate electrodes G1 to G4 may be provided as gates of various transistors for processing electrical signals generated from the first to fourth pixels PX1 to PX4, respectively. For example, each of the first to fourth gate electrodes G1 to G4 may be provided as a gate of at least one of the reset transistor RX, the source follower transistor SF, or the selection transistor SEL of FIG. 1.

In one or more embodiments, each of the first to fourth gate electrodes G1 to G4 may be disposed in the substrate 100. Upper surfaces GUS of the first to fourth gate electrodes G1 to G4 may be adjacent to (or in contact with) the first surface 100a of the substrate 100.

For example, a portion of each of the first to fourth gate electrodes G1 to G4 may be disposed in the shallow trench isolation pattern 110. Each of the first to fourth gate electrodes G1 to G4 may include a first buried portion BP1 disposed in the shallow trench isolation pattern 110 and a second buried portion BP2 disposed in the substrate 100. A thickness of the first buried portion BP1 may be greater than a thickness of the second buried portion BP2. A lower surface of the first buried portion BP1 may be positioned at a lower vertical level than a vertical level of a lower surface of the second buried portion BP2 in the third direction Z.

Each of the first to fourth transfer gate electrodes TG1 to TG4 and the first to fourth gate electrodes G1 to G4 may include a conductive material, for example, at least one of a metal film, a metal silicide film, an undoped silicon germanium film, an impurity-doped polysilicon film, or an impurity-doped silicon germanium film. However, embodiments are not limited thereto.

A connection pad 140 and a first pad, a second pad 152, a third pad 153, and a fourth pad 154 electrically connect the first to fourth floating diffusion regions FD1 to FD4 to each other. The connection pad 140 and the first to fourth pads 151 to 154 are in contact with the first to fourth floating diffusion regions FD1 to FD4. The connection pad 140 and the first to fourth pads 151 to 154 may be provided as the common node ND of FIG. 1.

The connection pad 140 may be disposed in the substrate 100 and between adjacent ones of the first to fourth floating diffusion regions FD1 to FD4 or on the substrate 100 and between adjacent ones of the first to fourth floating diffusion regions FD1 to FD4. In a plan view, the first to fourth floating diffusion regions FD1 to FD4 may be disposed adjacent to and/or around the connection pad 140. At least a portion of the connection pad 140 may overlap the shallow trench isolation pattern 110 in the third direction Z. At least a portion of the connection pad 140 may be disposed in the shallow trench isolation pattern 110.

In one or more embodiments, the connection pad 140 may be disposed in the substrate 100. The connection pad 140 may be adjacent to (or in contact with) the first surface 100a of the substrate 100.

A lower surface of the connection pad 140 may be positioned at a lower vertical level than a vertical level of the lower surfaces of the first to fourth floating diffusion regions FD1 to FD4 in the third direction Z.

The connection pad 140 may include a first extension portion 141 and a second extension portion 142. The first extension portion 141 may extend in the first direction X while being disposed between the first floating diffusion region FD1 and the third floating diffusion region FD3 and between the second floating diffusion region FD2 and the fourth floating diffusion region FD4. The second extension portion 142 may extend in the second direction Y while being disposed between the first floating diffusion region FD1 and the second floating diffusion region FD2 and between the third floating diffusion region FD3 and the fourth floating diffusion region FD4. The first extension portion 141 and the second extension portion 142 may intersect each other. The connection pad 140 may have a cross (+) shape in the plan view (e.g., in an XY plane).

The first pad 151 is disposed between the first floating diffusion region FD1 and the connection pad 140. The first pad 151 is in contact with the first floating diffusion region FD1 and the connection pad 140. The second pad 152 is disposed between the second floating diffusion region FD2 and the connection pad 140. The second pad 152 is in contact with the second floating diffusion region FD2 and the connection pad 140. The third pad 153 is disposed between the third floating diffusion region FD3 and the connection pad 140. The third pad 153 is in contact with the third floating diffusion region FD3 and the connection pad 140. The fourth pad 154 is disposed between the fourth floating diffusion region FD4 and the connection pad 140. The fourth pad 154 is in contact with the fourth floating diffusion region FD4 and the connection pad 140. A boundary may be defined between each of the first to fourth pads 151 to 154 and the connection pad 140.

In one or more embodiments, the first to fourth pads 151 to 154 may be spaced apart from each other. The first to fourth pads 151 to 154 may be connected to each other via the connection pad 140.

Each of the first to fourth pads 151 to 154 may include a connection portion C, a first extension portion E1, and a second extension portion E2.

The connection portion C may be disposed between the connection pad 140 and corresponding one of the first to fourth floating diffusion regions FD1 to FD4. The connection portion C may be in contact with the connection pad 140. The connection portion C may connect the first extension portion E1 and the second extension portion E2 to each other.

An upper surface CUS of the connection portion C may be positioned at a higher vertical level than a vertical level of the first surface 100a of the substrate 100 in the third direction Z. For example, the upper surface CUS of the connection portion C may be positioned at a lower vertical level than a vertical level of an upper surface 161US of the first insulating film 161. However, embodiments are not limited thereto.

The first extension portion E1 may extend from the connection portion C along a portion of the upper surface of corresponding one of the first to fourth floating diffusion regions FD1 to FD4. The first extension portion E1 may extend into a gate dielectric film 131 on the upper surface of the corresponding one of the first to fourth floating diffusion regions FD1 to FD4. The first extension portion E1 may be in contact with the corresponding one of the first to fourth floating diffusion regions FD1 to FD4. The upper surface CUS of the connection portion C is positioned at a higher vertical level than a vertical level of an upper surface E1US of the first extension portion E1 in the third direction Z.

The second extension portion E2 may extend from the connection portion C into the substrate 100. In one or more embodiments, the second extension portion E2 may be disposed in a portion of the substrate 100 between corresponding one of the first to fourth floating diffusion regions FD1 to FD4 and the connection pad 140. The second extension portion E2 may be interposed between the corresponding one of the first to fourth floating diffusion regions FD1 to FD4 and the connection pad 140. The second extension portion E2 may extend along a side surface of the corresponding one of the first to fourth floating diffusion regions FD1 to FD4 and/or a side surface of the connection pad 140. The second extension portion E2 may extend into a portion of the gate dielectric film 131 between the corresponding one of the first to fourth floating diffusion regions FD1 to FD4 and the connection pad 140. The second extension portion E2 may be in contact with the corresponding one of the first to fourth floating diffusion regions FD1 to FD4 and the connection pad 140.

The uppermost surface 150US of each of the first to fourth pads 151 to 154 is located at a different vertical level from vertical levels of the uppermost surface 140US of the connection pad 140, the upper surface TGUS of each of the first to fourth transfer gate electrodes TG1 to TG4, and the upper surface GUS of each of the first to fourth gate electrodes G1 to G4 in the third direction Z. The uppermost surface 150US of each of the first to fourth pads 151 to 154 may be the upper surface CUS of the connection portion C.

In one or more embodiments, the uppermost surface 150US of each of the first to fourth pads 151 to 154 is positioned at a higher vertical level than a vertical level of each of the uppermost surface 140US of the connection pad 140, the upper surface TGUS of each of the first to fourth transfer gate electrodes TG1 to TG4, and the upper surface GUS of each of the first to fourth gate electrodes G1 to G4 in the third direction Z.

For example, the upper surfaces TGUS of the first to fourth transfer gate electrodes TG1 to TG4 may be substantially coplanar with (or have substantially the same vertical level as those of) the upper surfaces GUS of the first to fourth gate electrodes G1 to G4 and the uppermost surface 140US of the connection pad 140. In this regard, substantially the same may include not only exactly the same but also a minute difference that may occur due to a process margin.

Each of the connection pad 140 and the first to fourth pads 151 to 154 may include a conductive material, for example, at least one of a metal film (e.g., tungsten, titanium, copper, aluminum, etc.), a metal silicide film, an undoped silicon germanium film or silicon, a polysilicon film doped with impurities (e.g., boron, phosphorus, arsenic, etc.), or a silicon germanium film doped with impurities. However, embodiments are not limited thereto. A concentration of the impurities in each of the first to fourth pads 151 to 154 may be different from a concentration of the impurities in the connection pad 140.

For example, the connection pad 140 and the first to fourth pads 151 to 154 may include the same conductive material (or having the same material composition) as that of the first to fourth transfer gate electrodes TG1 to TG4 and the first to fourth gate electrodes G1 to G4. For example, each of all of the connection pad 140, the first to fourth pads 151 to 154, the first to fourth transfer gate electrodes TG1 to TG4, and the first to fourth gate electrodes G1 to G4 may include a polysilicon film.

The gate dielectric film 131 may be interposed between the substrate 100 and each of the first to fourth transfer gate electrodes TG1 to TG4 and between the substrate 100 and each of the first to fourth gate electrodes G1 to G4. The gate dielectric film 131 may not be interposed between the shallow trench isolation pattern 110 and each of the first to fourth transfer gate electrodes TG1 to TG4 and between the shallow trench isolation pattern 110 and each of the first to fourth gate electrodes G1 to G4.

The gate dielectric film 131 may be interposed between the connection pad 140 and the substrate 100. A portion of the gate dielectric film 131 disposed on the connection pad 140 may extend along the first surface 100a of the substrate 100 so as to be disposed between the first to fourth transfer gate electrodes TG1 to TG4 and the substrate 100. The connection pad 140 and the first to fourth pads 151 to 154 are insulated from the substrate 100 via the gate dielectric film 131. The gate dielectric film 131 may not be interposed between the shallow trench isolation pattern 110 and the connection pad 140 and between the shallow trench isolation pattern 110 and the first to fourth pads 151 to 154.

The gate dielectric film 131 may include a dielectric material, for example, at least one of silicon oxide, silicon oxynitride, silicon nitride, or a relatively high-k dielectric material having a dielectric constant greater than that of silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof. However, embodiments are not limited thereto.

A first insulating film 161 may be disposed on the first surface 100a of the substrate 100. The first insulating film 161 may extend along the gate dielectric film 131 on the first surface 100a of the substrate 100, the upper surface of the shallow trench isolation pattern 110, the upper surfaces of the first to fourth transfer gate electrodes TG1 to TG4, the upper surfaces of the first to fourth gate electrodes G1 to G4, and the upper surface of the connection pad 140. The gate dielectric film 131 may be interposed between the substrate 100 and the first insulating film 161 and between the first to fourth floating diffusion regions FD1 to FD4 and the first insulating film 161. The first extension portion E1 may be interposed between the first to fourth floating diffusion regions FD1 to FD4 and the first insulating film 161. The first insulating film 161 may not cover the uppermost surfaces 150US of the first to fourth pads 151 to 154 so as to be exposed.

The first insulating film 161 may include an insulating material, for example, at least one of silicon oxide, silicon nitride, silicon oxynitride, silicon carbonitride, silicon oxycarbonitride, or a combination thereof. However, embodiments are not limited thereto. For example, the first insulating film 161 may include a material having an etch selectivity with respect to the gate dielectric film 131. The gate dielectric film 131 may include silicon oxide, and the first insulating film 161 may include silicon nitride.

A second insulating film 162 may be disposed on the first insulating film 161. A wiring pattern 166 may be disposed in the second insulating film 162. Each of a first contact 145 and a second contact 165 may be disposed in the first insulating film 161 and the second insulating film 162.

The first contact 145 may be disposed on the connection pad 140. The first contact 145 may be disposed in the first insulating film 161 and the second insulating film 162 and extend in the third direction Z to connect the wiring pattern 166 and the connection pad 140 to each other. One first contact 145 may be disposed on the connection pad 140. The first contact 145 may be formed, for example, in an area where the first extension portion 141 and the second extension portion 142 intersect each other. In FIG. 2, the arrangement of the first contact 145 is an example, and embodiments are not limited thereto.

Each of the second contacts 165 may be disposed in the first insulating film 161 and the second insulating film 162 and extend in the third direction Z to connect each of the first to fourth transfer gate electrodes TG1 to TG4 to the wiring pattern 166 and connect each of the first to fourth gate electrodes G1 to G4 to the wiring pattern 166. In FIGS. 3 and 4, the number of layers and the arrangement of the wiring pattern 166 are examples, and embodiments are not limited thereto.

The second insulating film 162 may include an insulating material, for example, at least one of silicon oxide, silicon nitride, silicon oxynitride, silicon carbonitride, silicon oxycarbonitride, or a combination thereof. However, embodiments are not limited thereto. The second insulating film 162 may be embodied as a single film or a stack of multi films. Each of the first contact 145, the second contact 165, and the wiring pattern 166 may include a conductive material, for example, a metal film or a metal silicide film. However, embodiments are not limited thereto.

A surface insulating film 160 may be formed on the second surface 100b of the substrate 100. The surface insulating film 160 may conformally extend along the second surface 100b of the substrate 100. The surface insulating film 160 may include an insulating material, for example, at least one of silicon oxide, silicon nitride, silicon oxynitride, aluminum oxide, hafnium oxide, and a combination thereof. However, embodiments are not limited thereto.

The surface insulating film 160 may be provided as an anti-reflection film to prevent reflection of light incident on the second surface 100b as a light-receiving surface. Accordingly, the light receiving percentage of the first to fourth photodiodes PD1 to PD4 may be improved. As another example, the surface insulating film 160 may be provided as a planarization film, thereby contributing to forming a color filter 180, a microlens 190, etc. which will be described later, at a uniform vertical level.

In one or more embodiments, the surface insulating film 160 may be formed as a stack of multiple films. In one or more embodiments, unlike the illustrated example, the surface insulating film 160 may include an aluminum oxide film, a hafnium oxide film, a silicon oxide film, a silicon nitride film, and a hafnium oxide film, which are sequentially stacked on the second surface 100b of the substrate 100.

A grid 170 may be formed on the surface insulating film 160. The grid 170 may be formed in a grid shape in a plan view (e.g., in an XY plane). For example, the grid 170 may be disposed to overlap at least a portion of the PD isolation pattern 120 in the third direction Z.

In one or more embodiments, the grid 170 may include a first grid film 172 and a second grid film 174. The first grid film 172 and the second grid film 174 may be sequentially stacked on the surface insulating film 160.

The first grid film 172 may include, for example, at least one of titanium (Ti), titanium nitride (TiN), tantalum (Ta), tantalum nitride (TaN), tungsten (W), aluminum (Al), copper (Cu), or a combination thereof. However, embodiments are not limited thereto. The first grid film 172 may prevent charges generated by electrostatic discharge (ESD) or the like from being accumulated on the surface (e.g., the second surface 100b) of the substrate 100, thereby more effectively preventing ESD bruise defects.

The second grid film 174 may include a relatively low refractive index material having a refractive index lower than a refractive index of silicon (Si). For example, the second grid film 174 may include at least one of silicon oxide, aluminum oxide, tantalum oxide, and a combination thereof. However, embodiments are not limited thereto. The second grid film 174 refracts or reflects light obliquely incident on the second surface 100b as a light receiving surface, thereby improving the light condensing efficiency of each of the first to fourth pixels PX1 to PX4.

A first protective film 176 may be formed on the surface insulating film 160 and the grid 170. The first protective film 176 may conformally extend along profiles of the surface insulating film 160 and the grid 170. The first protective film 176 may prevent damage to the surface insulating film 160 and the grid 170. The first protective film 176 may include, for example, aluminum oxide (AlO). However, embodiments are not limited thereto.

The color filter 180 may be formed on the first protective film 176. The color filter 180 may have various colors according to unit pixels. For example, the color filter 180 may include a red color filter, a green color filter, a blue color filter, a yellow color filter, a magenta color filter, and a cyan color filter, or may further include a white color filter.

The microlens 190 may be formed on the color filter 180. The microlens 190 may have a convex shape and may have a predetermined radius of curvature. Accordingly, the microlens 190 may condense light incident on the first to fourth photodiodes PD1 to PD4. The microlens 190 may include, for example, a light-transmissive resin. However, embodiments of the present disclosure are not limited thereto.

In one or more embodiments, the microlens 190 may be formed on each of the first to fourth pixels PX1 to PX4.

A second protective film 195 may be formed on the microlens 190. The second protective film 195 may extend along the surface of the microlens 190. The second protective film 195 may include, for example, an inorganic oxide film such as a silicon oxide film, a titanium oxide film, a zirconium oxide film, or a hafnium oxide film. However, embodiments of the present disclosure are not limited thereto. For example, the second protective film 195 may include low temperature oxide (LTO).

The second protective film 195 may protect the microlens 190 from the outside. For example, the second protective film 195 may include an inorganic oxide film to protect the microlens 190 including an organic material. In addition, the second protective film 195 may improve the light condensing efficiency of the microlens 190, thereby improving the quality of the image sensor. For example, the second protective film 195 may fill a space between the microlenses 190, thereby reducing reflection, refraction, scattering, and the like of incident light reaching the space between the microlenses 190.

The plurality of floating diffusion regions FD respectively disposed in the plurality of pixels PX may be connected to each other via a wiring which extends across the plurality of pixels PX and is in contact with the plurality of floating diffusion regions FD. As another example, the plurality of floating diffusion regions FD respectively disposed in the plurality of pixels PX may be connected to each other via a contact and a wiring. For example, the plurality of floating diffusion regions FD may be connected to each other via a contact on each floating diffusion region FD and a wiring connecting the contacts to each other. In this case, parasitic capacitance may be generated between the contact formed on each floating diffusion region and the transfer gate electrode or the gate electrode, and thus a conversion gain of the image sensor may be reduced and noise may be increased. In addition, the contact and the transfer gate electrode TG and/or the gate electrode GE may be formed in the same manufacturing process step, thereby causing interference in the manufacturing process of the transfer gate electrode TG and/or the gate electrode GE.

However, in the image sensor according to one or more embodiments, the first to fourth floating diffusion regions FD1 to FD4 are connected to each other via the connection pad 140 and the first to fourth pads 151 to 154, and one first contact 145 is disposed on the connection pad 140. Since the number of the first contacts 145 for connecting the first to fourth floating diffusion regions FD1 to FD4 to each other is reduced, the parasitic capacitance between the first to fourth transfer gate electrodes TG1 to TG4 or the first to fourth gate electrodes G1 to G4 and the first contact 145 may be reduced. Accordingly, an image sensor with improved conversion gain and reduced noise may be provided.

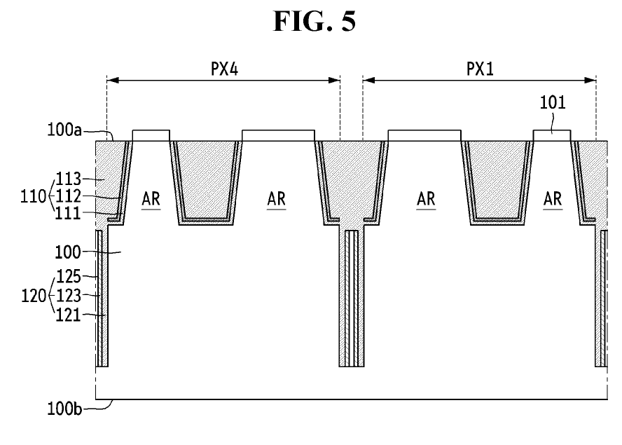

FIGS. 5 to 18 are diagrams illustrating intermediate structures corresponding to intermediate steps of a method for manufacturing an image sensor according to one or more embodiments. For convenience of description, contents duplicate with those as described above with reference to FIGS. 1 to 4 will be briefly described or descriptions thereof will be omitted.

Referring to FIGS. 2 and 5, the shallow trench isolation pattern 110 and the PD isolation pattern 120 are formed in the substrate 100. For example, a shallow trench isolation pattern extending from the first surface 100a to define the active area AR may be formed in the substrate 100 using a pad pattern 101. The shallow trench isolation pattern 110 may fill at least a portion of the element isolation trench. The pad pattern 101 may include, for example, nitride.

A deep trench (hereinafter, referred to as a pixel isolation trench) defining the plurality of pixels PX1 to PX4 may be formed in the substrate 100. The PD isolation pattern 120 may fill at least a portion of the pixel isolation trench. For example, the shallow trench isolation pattern 110 and the PD isolation pattern 120 may be connected to each other. The pad pattern 101 may be removed.

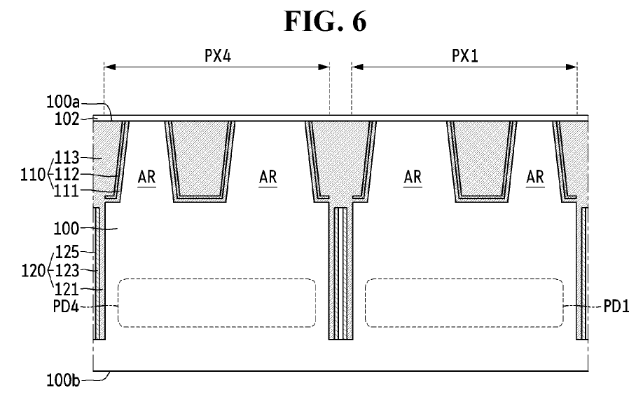

Referring to FIGS. 2 and 6, the first to fourth photodiodes PD1 to PD4 are formed in the substrate 100. For example, the first to fourth photodiodes PD1 to PD4 may be formed by ion-implanting n-type impurities into the p-type substrate 100.

A sacrificial insulating film 102 may be formed on the first surface 100a of the substrate 100. The sacrificial insulating film 102 may extend along the first surface 100a of the substrate 100. Unlike the illustrated example, the sacrificial insulating film 102 may be omitted.

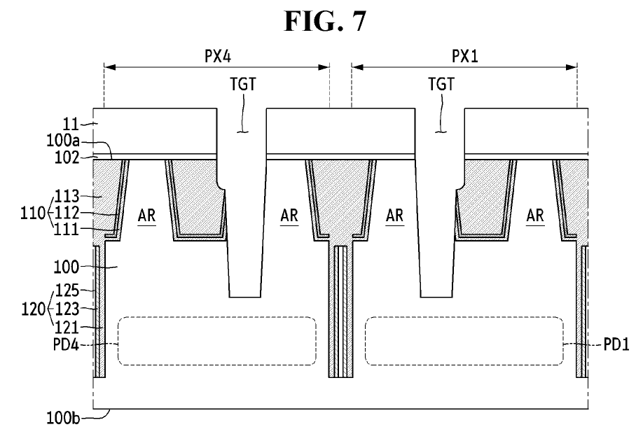

Referring to FIGS. 2 and 7, a transfer gate trench TGT is formed in the substrate 100.

The transfer gate trench TGT may be formed in the substrate 100 of each of the first to fourth pixels PX1 to PX4. For example, a mask pattern 11 may be formed on the sacrificial insulating film 102, and a transfer gate trench TGT may be formed in the substrate 100 using the mask pattern 11. The mask pattern 11 may be removed.

The transfer gate trenches TGT of the first to fourth pixels PX1 to PX4 may be adjacent to the first to fourth floating diffusion regions FD1 to FD4, respectively. The transfer gate trench TGT may extend from the first surface 100a. A depth of the transfer gate trench TGT in the shallow trench isolation pattern 110 may be different from a depth of the transfer gate trench TGT in the substrate 100 in the third direction Z. The depth of the transfer gate trench TGT in the shallow trench isolation pattern 110 may be less than the depth of the transfer gate trench TGT in the substrate 100 in the third direction Z.

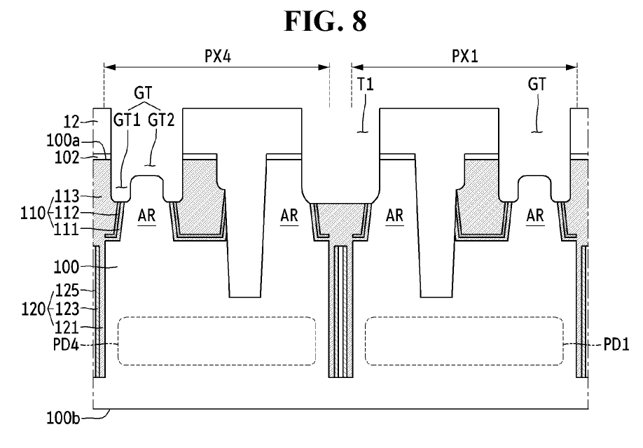

Referring to FIGS. 2 and 8, a first trench T1 and a gate trench GT are formed in the substrate 100. For example, a mask pattern 12 may be formed on the sacrificial insulating film 102 so as to fill the transfer gate trench TGT, and the first trench T1 and the gate trench GT may be formed in the substrate 100 using the mask pattern 12. The mask pattern 12 may be removed. As another example, the first trench T1 and the gate trench GT may be formed using different mask patterns.

The first trench T1 may be formed between the first to fourth floating diffusion regions FD1 to FD4. The first trench T1 may be formed in the substrate 100 and between the first to fourth pixels PX1 to PX4. At least a portion of the first trench T1 may be formed in the shallow trench isolation pattern 110.

The gate trench GT may be formed in each of the first to fourth pixels PX1 to PX4. The gate trench GT may include a first trench portion GT1 in the shallow trench isolation pattern 110 and a second trench portion GT2 in the substrate 100. A depth of the first trench portion GT1 may be different from a depth of the second trench portion GT2. The depth of the first trench portion GT1 may be greater than the depth of the second trench portion GT2. The maximum depth of the transfer gate trench TGT may be greater than each of the depth of the first trench T1 and the maximum depth of the gate trench GT.

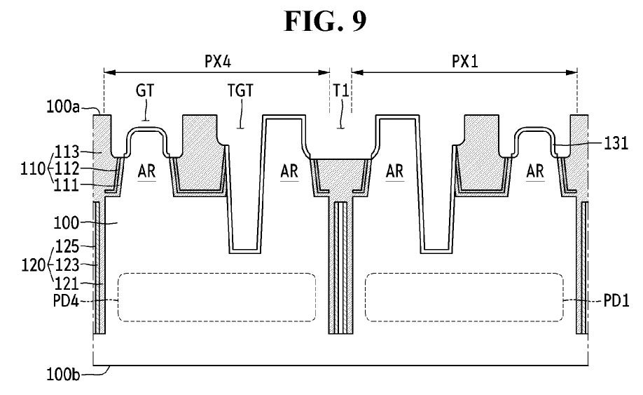

Referring to FIGS. 2 and 9, the gate dielectric film 131 is formed.

The gate dielectric film 131 may be formed along the substrate 100 and may not be formed along the shallow trench isolation pattern 110. The gate dielectric film 131 may be formed along the first surface 100a of the substrate 100, a portion of the substrate 100 exposed through the transfer gate trench TGT, a portion of the substrate 100 exposed through the first trench T1, and a portion of the substrate 100 exposed through the gate trench GT. For example, the gate dielectric film 131 may be a silicon oxide film grown from the substrate 100. A cleaning process may be performed before the gate dielectric film 131 is formed.

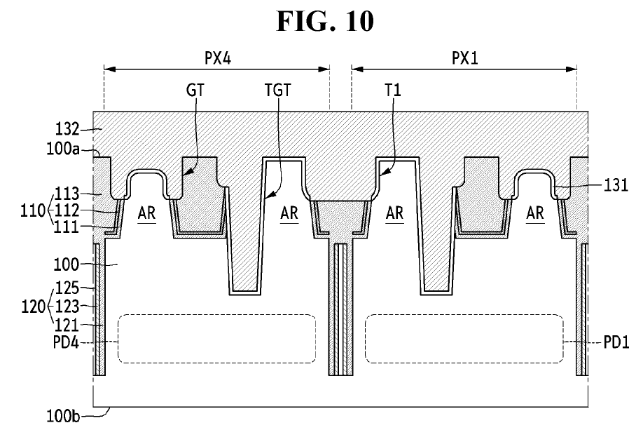

Referring to FIGS. 2 and 10, a preliminary gate electrode film 132 is formed on the first surface 100a of the substrate 100. The preliminary gate electrode film 132 may conformally extend on the resultant structure of FIG. 9. The preliminary gate electrode film 132 may fill the transfer gate trench TGT, the gate trench GT, and the first trench T1.

The preliminary gate electrode film 132 may be a polysilicon film. For example, after a polysilicon film is formed, an ion implantation process may be performed on the polysilicon film to form the preliminary gate electrode film 132 into which the impurities are implanted. In another example, the impurities may be implanted into the polysilicon film by performing an in-situ low pressure chemical vapor deposition (LPCVD) process on the polysilicon film.

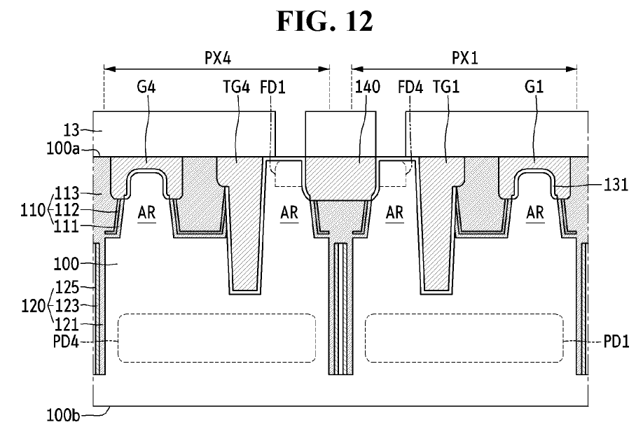

In still another example, the preliminary gate electrode film 132 which is the polysilicon film may be formed in the step of FIG. 10, and the impurities may be implanted thereto by performing an ion implantation process on the first to fourth transfer gate electrodes TG1 to TG4, the first to fourth gate electrodes G1 to G4, and the connection pad 140 as the polysilicon films, in the step of FIG. 12 to be described later. Each of the first to fourth transfer gate electrodes TG1 to TG4, the first to fourth gate electrodes G1 to G4, and the connection pad 140 may be formed via an ion implantation process using a mask pattern. That is, each of the first to fourth transfer gate electrodes TG1 to TG4, the first to fourth gate electrodes G1 to G4, and the connection pad 140 may independently have an impurity, a concentration of the impurity, a depth of the impurity, etc.

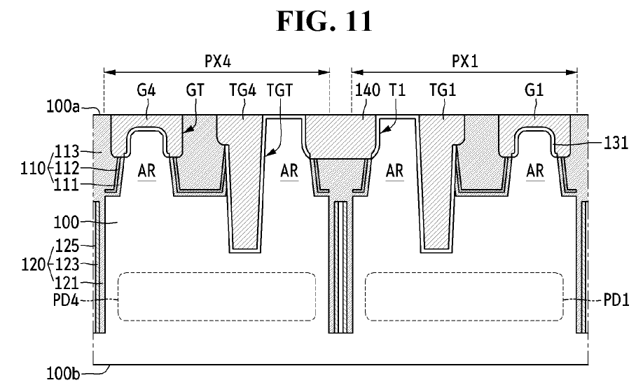

Referring to FIGS. 2 and 11, the preliminary gate electrode film 132 of FIG. 10 is patterned to form the first to fourth transfer gate electrodes TG1 to TG4, the first to fourth gate electrodes G1 to G4, and the connection pad 140 in the substrate 100. Each of the first to fourth transfer gate electrodes TG1 to TG4 may fill the transfer gate trench TGT of each of the first to fourth pixels PX1 to PX4. Each of the first to fourth gate electrodes G1 to G4 may fill the gate trench GT of each of the first to fourth pixels PX1 to PX4. The connection pad 140 may fill the first trench T1.

For example, the first to fourth transfer gate electrodes TG1 to TG4, the first to fourth gate electrodes G1 to G4, and the connection pad 140 may be formed by performing a chemical mechanical planarization process or an etch-back process on the preliminary gate electrode film 132 of FIG. 10. The gate dielectric film 131 and the shallow trench isolation pattern 110 may be exposed. As another example, the first to fourth transfer gate electrodes TG1 to TG4, the first to fourth gate electrodes G1 to G4, and the connection pad 140 may be formed by performing a dry etching process using a mask pattern on the preliminary gate electrode film 132 of FIG. 10.

Referring to FIGS. 2 and 12, an ion implantation process is performed on the substrate 100. An ion implantation process may be performed on the active area AR.

For example, first to fourth floating diffusion regions FD1 to FD4 may be formed in the substrate 100 using a mask pattern 13. A source/drain area SD adjacent to the first to fourth gate electrodes G1 to G4 may be formed. The mask pattern 13 may be removed.

A heat treatment process may be performed after the ion implantation process. The heat treatment process may include, for example, at least one of a batch annealing process, a spike rapid thermal annealing process, a flash rapid thermal annealing process, a laser spike annealing process, or microwave spike annealing. However, embodiments are not limited thereto.

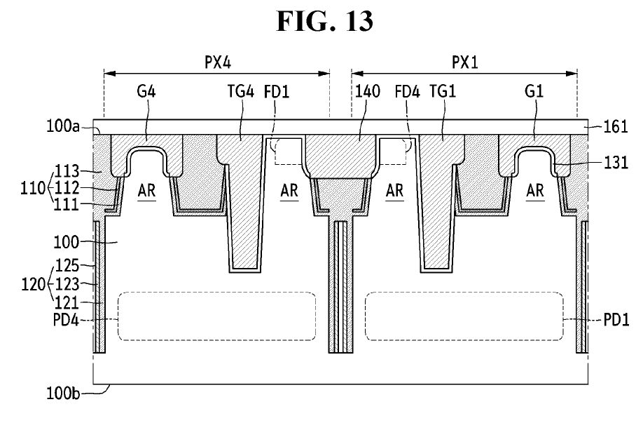

Referring to FIGS. 2 and 13, the first insulating film 161 is formed on the first surface 100a of the substrate 100. The first insulating film 161 may be formed on the shallow trench isolation pattern 110, the gate dielectric film 131, the first to fourth gate electrodes G1 to G4, and the first to fourth transfer gate electrodes TG1 to TG4.

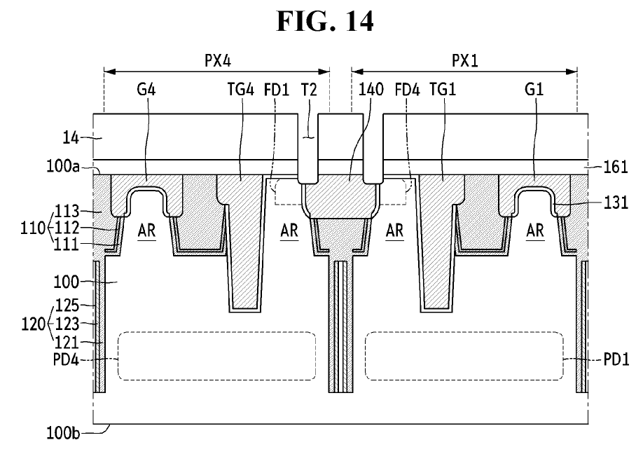

Referring to FIGS. 2 and 14, a second trench T2 is formed in the first insulating film 161 and the substrate 100. The second trench T2 may be formed in each of the first to fourth pixels PX1 to PX4. The second trench T2 may be formed between each of the first to fourth floating diffusion regions FD1 to FD4 and the connection pad 140.

For example, a mask pattern 14 may be formed on the first insulating film 161, and a second trench T2 extending through the first insulating film 161, the gate dielectric film 131, and a portion of the substrate 100 may be formed using the mask pattern 14. The second trench T2 may extend from the upper surface of the first insulating film 161 into the substrate 100. The second trench T2 may expose the gate dielectric film 131, the first to fourth floating diffusion regions FD1 to FD4, and the connection pad 140 therethrough. The mask pattern 14 may be removed.

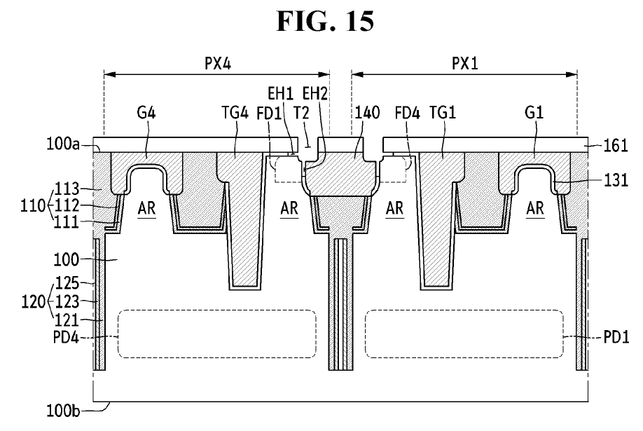

Referring to FIGS. 2 and 15, a portion of the gate dielectric film 131 exposed through the second trench T2 is removed to form a first extension hole EH1 and a second extension hole EH2. The first extension hole EH1 and the second extension hole EH2 may be formed in each of the first to fourth pixels PX1 to PX4. The first extension hole EH1 may be formed by removing a portion of the gate dielectric film 131 on the upper surface of each of the first to fourth floating diffusion regions FD1 to FD4. The first extension hole EH1 may expose a portion of each of the first to fourth floating diffusion regions FD1 to FD4. The second extension hole EH2 may be formed between each of the first to fourth floating diffusion regions FD1 to FD4 and the connection pad 140. The second extension hole EH2 may be formed by removing a portion of the gate dielectric film 131 interposed between each of the first to fourth floating diffusion regions FD1 to FD4 and the connection pad 140. The second extension hole EH2 may expose a side surface of each of the first to fourth floating diffusion regions FD1 to FD4 (or a side surface of the connection pad 140 adjacent to each of the first to fourth floating diffusion regions FD1 to FD4) therethrough.

The gate dielectric film 131 may be removed by, for example, a radical etching process. For example, the gate dielectric film 131 may be removed by a radical dry etching process, and thus an oxide film may not be formed from the substrate 100.

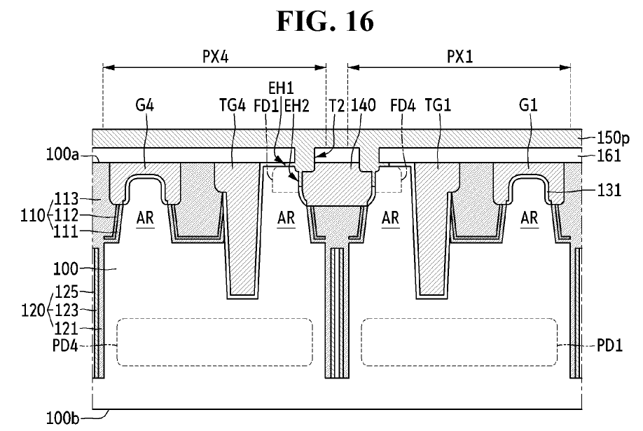

Referring to FIGS. 2 and 16, a preliminary pad film 150p is formed on the first insulating film 161. The preliminary pad film 150p fills the second trench T2, the first extension hole EH1, and the second extension hole EH2. The preliminary pad film 150p is in contact with the connection pad 140 and the first to fourth floating diffusion regions FD1 to FD4.

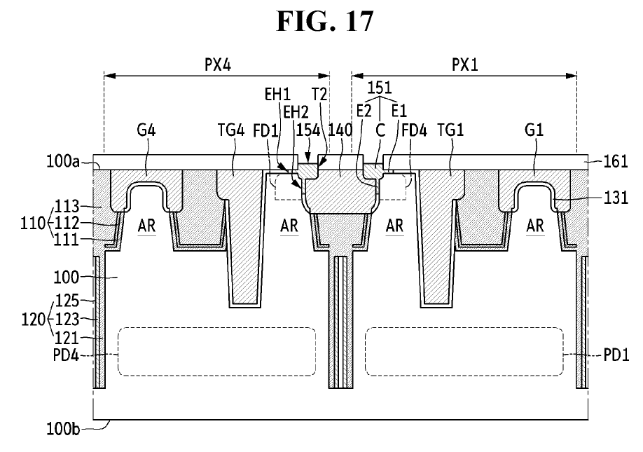

Referring to FIGS. 2 and 17, the preliminary pad film 150p of FIG. 16 is patterned to form the first to fourth pads 151 to 154. Each of the first to fourth pads 151 to 154 may fill at least a portion of the second trench T2 of each of the first to fourth pixels PX1 to PX4. The first extension portion E1 may fill the first extension hole EH1. The second extension portion E2 may fill the second extension hole EH2. The connection portion C may fill at least a portion of the second trench T2.

For example, the first to fourth pads 151 to 154 may be formed by performing a chemical mechanical planarization process or an etch-back process on the preliminary pad film 150p of FIG. 16.

In the method for manufacturing an image sensor according to one or more embodiments, the first to fourth transfer gate electrodes TG1 to TG4, the first to fourth gate electrodes G1 to G4, and the connection pad 140 are formed in the same manufacturing process, and then, the first insulating film 161 is formed, and then, the first to fourth pads 151 to 154 are formed. Accordingly, the connection pad 140 and the first to fourth pads 151 to 154 may not affect the manufacturing process of the first to fourth transfer gate electrodes TG1 to TG4 and the first to fourth gate electrodes G1 to G4 and/or the manufacturing process of the first to fourth floating diffusion regions FD1 to FD4.

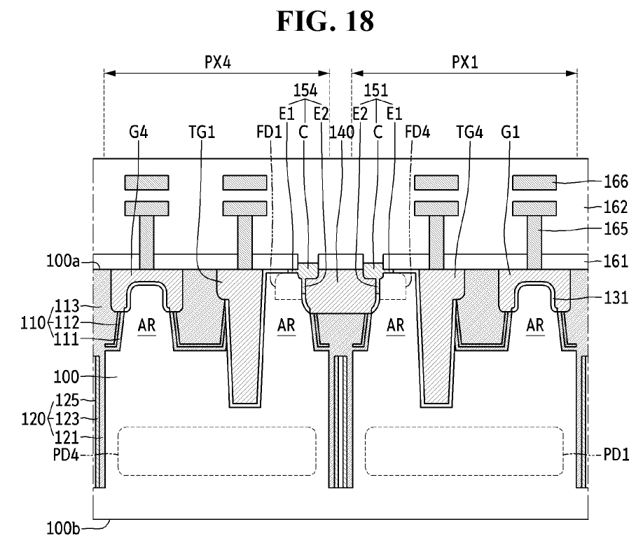

Referring to FIGS. 2 and 18, the second insulating film 162, the first contact 145, the second contact 165, and the wiring pattern 166 are formed on the first insulating film 161.

The first contact 145 may be electrically connected to the first to fourth pads 151 to 154. The second contact 165 may be electrically connected to each of the first to fourth transfer gate electrodes TG1 to TG4 and each of the first to fourth gate electrodes G1 to G4. The first contact 145 and the second contact 165 may be formed at the same vertical level. The wiring pattern 166 electrically connected to the first contact 145 and/or the second contact 165 may be formed.

Referring to FIGS. 2 and 3, a back grinding process may be performed on the second surface 100b of the substrate 100. As the back-grinding process is performed, the PD isolation pattern 120 may not be covered with the second surface 100b of the substrate 100 so as to be exposed. For example, the PD isolation pattern 120 extending through an entirety of the substrate 100 may be provided.

The surface insulating film 160, the grid 170, the first protective film 176, the color filter 180, the microlens 190, and the second protective film 195 may be formed on the second surface 100b of the substrate 100.

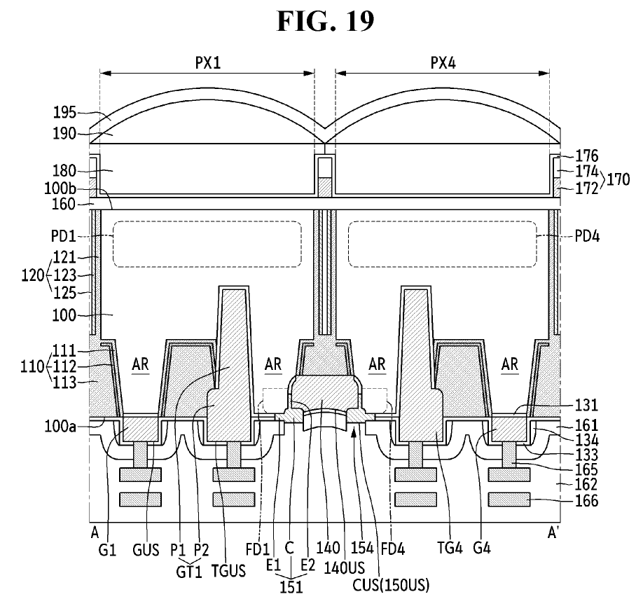

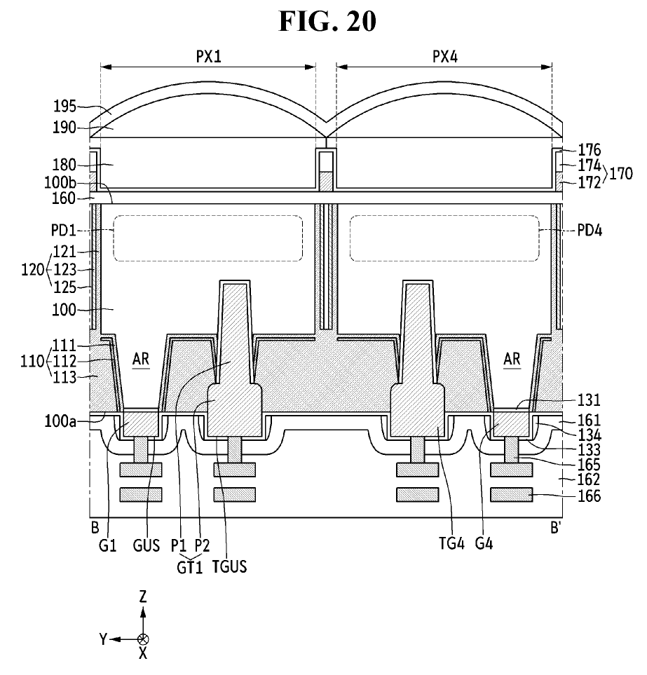

FIGS. 19 and 20 are further cross-sectional views for illustrating an image sensor according to one or more embodiments. For convenience of description, contents duplicate with those as described above with reference to FIGS. 1 to 18 will be briefly described or descriptions thereof will be omitted.

Referring to FIGS. 2, 19, and 20, in the image sensor according to one or more embodiments, each of the first to fourth transfer gate electrodes TG1 to TG4 may include a first portion P1 disposed in the substrate 100 and a second portion P2 disposed on the first surface 100a of the substrate 100. The second portion P2 may protrude from the first surface 100a of the substrate 100.

In one or more embodiments, each of the first to fourth gate electrodes G1 to G4 may be disposed on the first surface 100a of the substrate 100. Each of the first to fourth gate electrodes G1 to G4 may protrude from the first surface 100a of the substrate 100.

For example, the upper surfaces TGUS of the first to fourth transfer gate electrodes TG may be substantially coplanar with the upper surfaces GUS of the first to fourth gate electrodes G1 to G4 and the uppermost surface 140US of the connection pad 140. However, embodiments are not limited thereto.

In one or more embodiments, the uppermost surfaces 150US of the first to fourth pads 151 to 154 are positioned at a higher vertical level than a vertical level of the uppermost surface 140US of the connection pad 140, and are positioned at a lower vertical level than a vertical level of each of the upper surfaces TGUS of the first to fourth transfer gate electrodes TG and the upper surfaces GUS of the first to fourth gate electrodes G1 to G4 in the third direction Z.

In one or more embodiments, the protective insulating film 133 may extend along the gate dielectric film 131 on the first surface 100a of the substrate 100, the upper surface of the shallow trench isolation pattern 110, the upper surface of the connection pad 140, the profiles of the first to fourth gate electrodes G1 to G4 on the first surface 100a of the substrate 100, and the profiles of the first to fourth transfer gate electrodes TG1 to TG4 on the first surface 100a of the substrate 100. The first extension portion E1 may extend into the gate dielectric film 131 and the protective insulating film 133.

The protective insulating film 133 may include an insulating material, for example, at least one of silicon oxide, silicon nitride, silicon oxynitride, or a combination thereof. However, embodiments are not limited thereto. The shallow trench isolation pattern 110 may include, for example, silicon oxide. As another example, the protective insulating film 133 may be omitted.

In one or more embodiments, a gate spacer 134 may be disposed on a side surface of each of the first to fourth gate electrodes G1 to G4. The gate spacer 134 may be disposed on the protective insulating film 133. The gate spacer 134 may be disposed on a side surface of the second portion P2 of each of the first to fourth transfer gate electrodes TG1 to TG4. The gate spacer 134 may include an insulating material, for example, at least one of silicon oxide, silicon nitride, silicon oxynitride, silicon oxycarbide, silicon boron nitride, silicon boron carbonitride, silicon oxycarbonitride, and combinations thereof. However, embodiments are not limited thereto.

The first insulating film 161 may extend along the protective insulating film 133 and the gate spacer 134. The protective insulating film 133 may be interposed between the connection pad 140 and the first insulating film 161, between the first to fourth transfer gate electrodes TG1 to TG4 and the first insulating film 161, between the first to fourth gate electrodes G1 to G4 and the first insulating film 161, between the first to fourth transfer gate electrodes TG1 to TG4 and the gate spacer 134, and between the first to fourth gate electrodes G1 to G4 and the gate spacer 134. The first insulating film 161 and the protective insulating film 133 may not cover the uppermost surfaces 150US of the first to fourth pads 151 to 154 so as to be exposed.

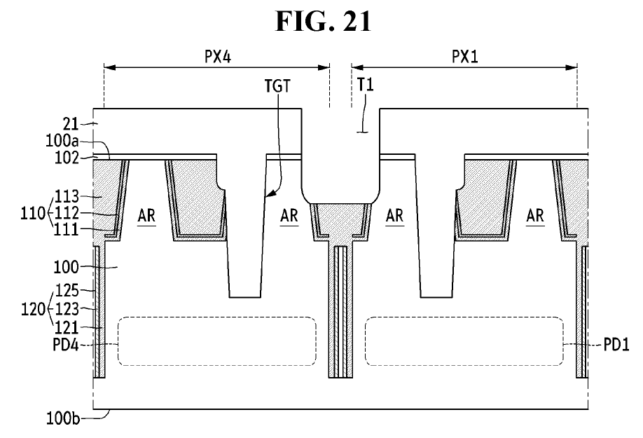

FIGS. 21 to 28 are diagrams illustrating intermediate structures corresponding to intermediate steps of a method for manufacturing an image sensor according to one or more embodiments. For convenience of description, contents duplicate with those as described above with reference to FIGS. 1 to 20 will be briefly described or descriptions thereof will be omitted. FIG. 21 is a diagram of an intermediate structure corresponding to an intermediate step after FIG. 7.

Referring to FIGS. 2 and 21, the first trench T1 is formed in the substrate 100.

For example, a mask pattern 21 may be formed on the sacrificial insulating film 102 so as to fill the transfer gate trench TGT, and the first trench T1 may be formed in the substrate 100 using the mask pattern 21. The mask pattern 21 may be removed.

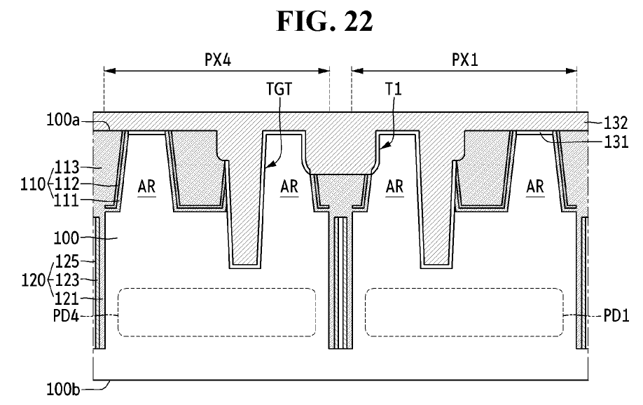

Referring to FIGS. 2 and 22, the gate dielectric film 131 and the preliminary gate electrode film 132 are formed. The gate dielectric film 131 may be formed along the substrate 100 and may not be formed along the shallow trench isolation pattern 110. The preliminary gate electrode film 132 may fill the transfer gate trench TGT and the first trench T1.

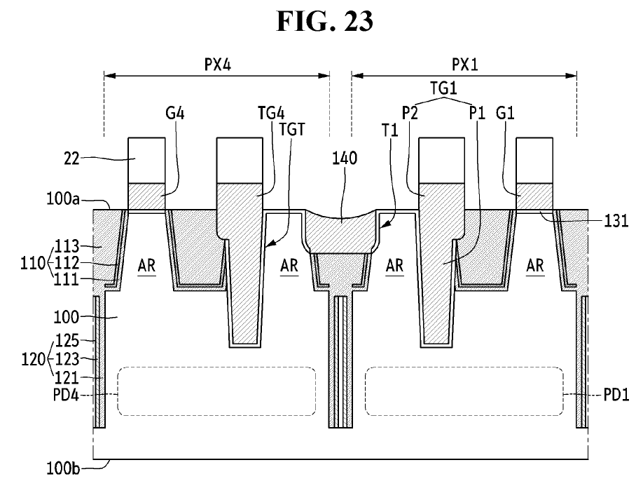

For example, the preliminary gate electrode film 132 including the polysilicon film into which impurities are implanted may be formed in the step of FIG. 22. In another example, the preliminary gate electrode film 132 including the polysilicon film may be formed in the step of FIG. 22, and the impurities may be implanted thereto by performing an ion implantation process on the first to fourth transfer gate electrodes TG1 to TG4, the first to fourth gate electrodes G1 to G4, and the connection pad 140 as the polysilicon films, in the step of FIG. 23 to be described later.

Referring to FIGS. 2 and 23, the preliminary gate electrode film 132 of FIG. 22 is patterned to form the first to fourth transfer gate electrodes TG1 to TG4, the first to fourth gate electrodes G1 to G4, and the connection pad 140. Each of the first to fourth transfer gate electrodes TG1 to TG4 may include the first portion P1 filling the transfer gate trench TGT of each of the first to fourth pixels PX1 to PX4 and the second portion P2 protruding from the first portion P1. Each of the first to fourth gate electrodes G1 to G4 may be formed on the active area AR of each of the first to fourth pixels PX1 to PX4. The connection pad 140 may fill the first trench T1.

For example, a mask pattern 22 may be formed on the preliminary gate electrode film 132 of FIG. 22. The first to fourth transfer gate electrodes TG1 to TG4, the first to fourth gate electrodes G1 to G4, and the connection pad 140 may be formed by performing a chemical mechanical planarization process or an etch-back process on a portion of the preliminary gate electrode film 132 not covered with the mask pattern 22 so as to be exposed. In this regard, the upper surface of the connection pad 140 may be concave toward the substrate 100 due to a relatively large width of the connection pad 140. However, embodiments are not limited thereto. The mask pattern 22 may be removed.

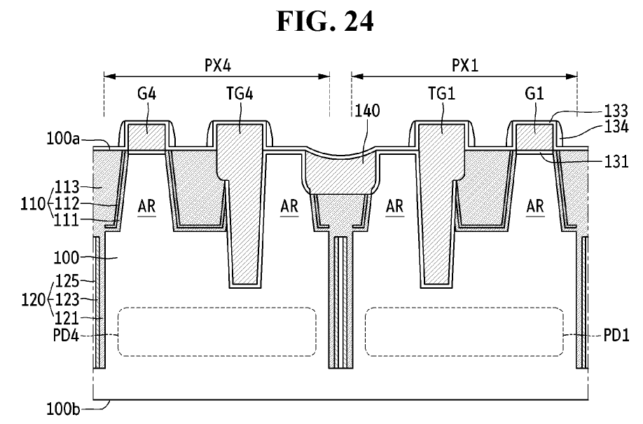

Referring to FIGS. 2 and 24, the protective insulating film 133 may be formed on the first surface 100a of the substrate 100. The gate spacer 134 is formed on the side surface of each of the first to fourth transfer gate electrodes TG1 to TG4 and the side surface of each of the first to fourth gate electrodes G1 to G4.

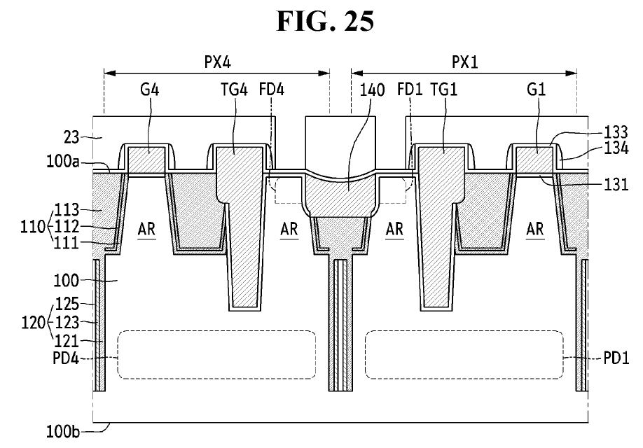

Referring to FIGS. 2 and 25, an ion implantation process is performed on the substrate 100.

For example, the first to fourth floating diffusion regions FD1 to FD4 may be formed in the substrate 100 using a mask pattern 23. The source/drain area SD adjacent to the first to fourth gate electrodes G1 to G4 may be formed. A heat treatment process may be performed after the ion implantation process. The mask pattern 23 may be removed.

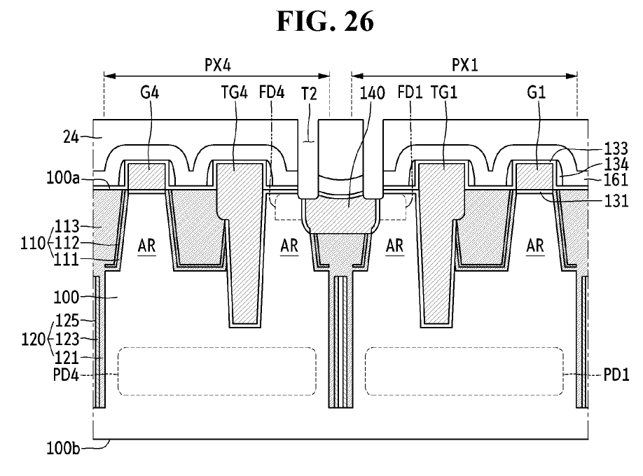

Referring to FIGS. 2 and 26, the first insulating film 161 is formed on the first surface 100a of the substrate 100. The first insulating film 161 may extend along the protective insulating film 133 and the gate spacer 134.

The second trench T2 is formed in the first insulating film 161, the protective insulating film 133, the gate dielectric film 131, and the substrate 100. For example, a mask pattern 24 may be formed on the first insulating film 161. The second trench T2 may be formed using the mask pattern 24 so as to extend through the first insulating film 161, the protective insulating film 133, and the gate dielectric film 131 and to extend through a portion of the substrate 100. The second trench T2 may expose a portion of each of the protective insulating film 133, the gate dielectric film 131, the first to fourth floating diffusion regions FD1 to FD4, and a portion of the connection pad 140. The mask pattern 24 may be removed.

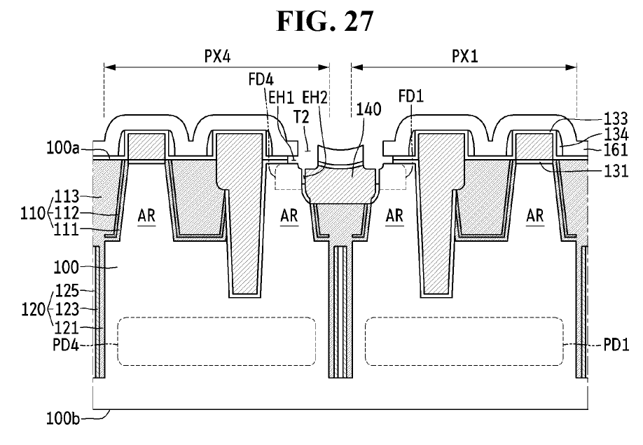

Referring to FIGS. 2 and 27, a portion of the gate dielectric film 131 and a portion of the protective insulating film 133 exposed through the second trench T2 are removed to form the first extension hole EH1 and the second extension hole EH2. The first extension hole EH1 may be formed by removing a portion of the gate dielectric film 131 and a portion of the protective insulating film 133 on the upper surface of each of the first to fourth floating diffusion regions FD1 to FD4. The gate dielectric film 131 and the protective insulating film 133 may be removed by, for example, a radical etching process.

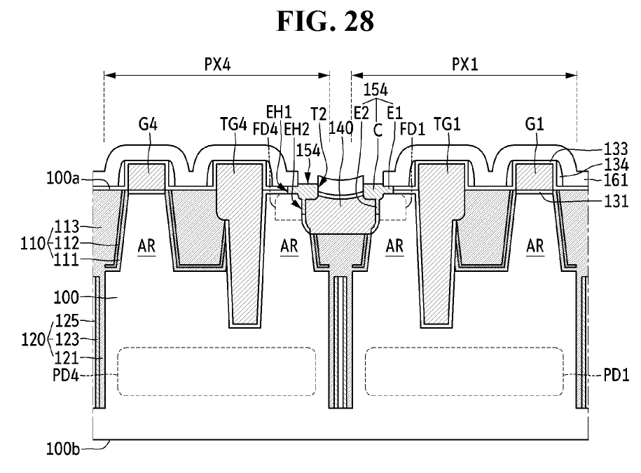

Referring to FIGS. 2 and 28, the first to fourth pads 151 to 154 are formed. Each of the first to fourth pads 151 to 154 may fill at least a portion of the second trench T2 of each of the first to fourth pixels PX1 to PX4. The first extension portion E1 may fill the first extension hole EH1. The second extension portion E2 may fill the second extension hole EH2. The connection portion C may fill at least a portion of the second trench T2.

Referring to FIGS. 2 and 19, the second insulating film 162, the first contact 145, the second contact 165, and the wiring pattern 166 are formed on the first insulating film 161. A back grinding process may be performed on the second surface 100b of the substrate 100. The surface insulating film 160, the grid 170, the first protective film 176, the color filter 180, the microlens 190, and the second protective film 195 may be formed on the second surface 100b of the substrate 100.

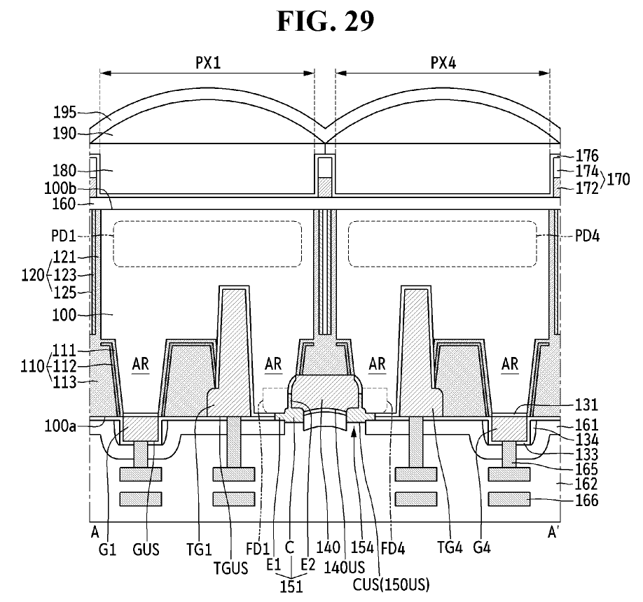

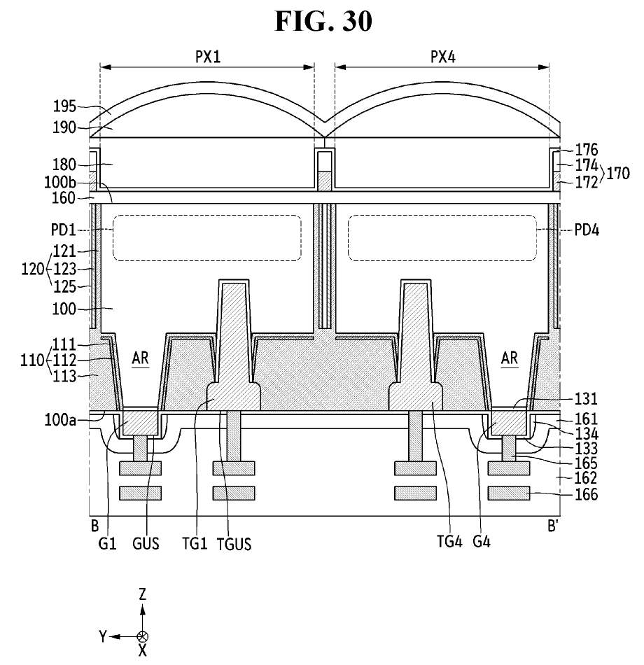

FIGS. 29 and 30 are further cross-sectional views for illustrating an image sensor according to one or more embodiments. For convenience of description, contents duplicate with those as described above with reference to FIGS. 1 to 28 will be briefly described or descriptions thereof will be omitted.

Referring to FIGS. 2, 29, and 30, in the image sensor according to one or more embodiments, each of the first to fourth transfer gate electrodes TG1 to TG4 may be disposed in the substrate 100, and each of the first to fourth gate electrodes G1 to G4 may be disposed on the first surface 100a of the substrate 100. The upper surfaces TGUS of the first to fourth transfer gate electrodes TG may be positioned at a lower vertical level than a vertical level of each of the upper surfaces GUS of the first to fourth gate electrodes G1 to G4.

The uppermost surfaces 150US of the first to fourth pads 151 to 154 may be positioned at a higher vertical level than a vertical level of each of the uppermost surface 140US of the connection pad 140 and the upper surfaces TGUS of the first to fourth transfer gate electrodes TG, and may be positioned at a lower vertical level than a vertical level of each of the upper surfaces GUS of the first to fourth gate electrodes G1 to G4 in the third direction Z.

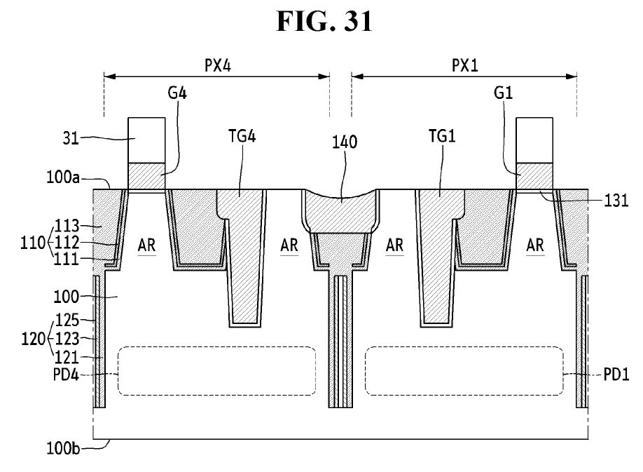

FIG. 31 is a diagram illustrating an intermediate structure corresponding to an intermediate step of a method for manufacturing an image sensor according to one or more embodiments. For convenience of description, contents duplicate with those as described above with reference to FIGS. 1 to 30 will be briefly described or descriptions thereof will be omitted. FIG. 31 is a diagram of an intermediate structure corresponding to an intermediate step after FIG. 22.

Referring to FIG. 31, the preliminary gate electrode film 132 of FIG. 22 is patterned to form the first to fourth transfer gate electrodes TG1 to TG4, the first to fourth gate electrodes G1 to G4, and the connection pad 140.

For example, a mask pattern 31 may be formed on the preliminary gate electrode film 132 of FIG. 22, and the first to fourth transfer gate electrodes TG1 to TG4, the first to fourth gate electrodes G1 to G4, and the connection pad 140 may be formed by performing a chemical mechanical planarization process or an etch-back process on a portion of the preliminary gate electrode film 132 not covered with the mask pattern 31. The mask pattern 31 may be removed.

The manufacturing process as above-described with reference to FIGS. 24 to 28 may be performed, and the image sensor as above-described with reference to FIGS. 29 and 30 may be formed.

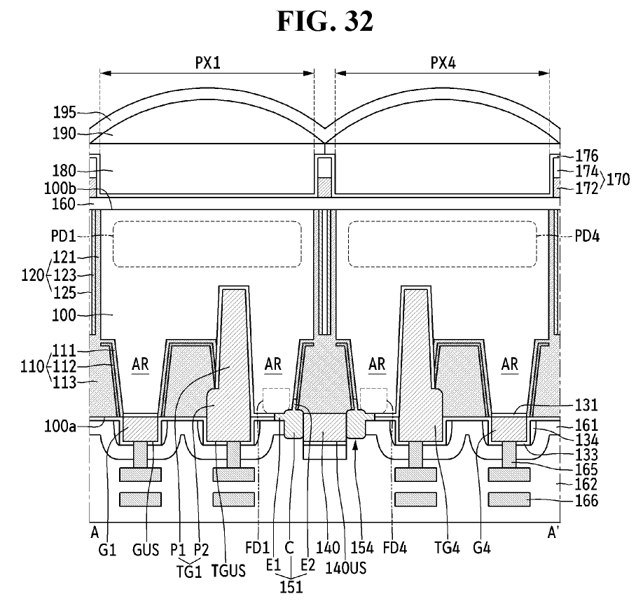

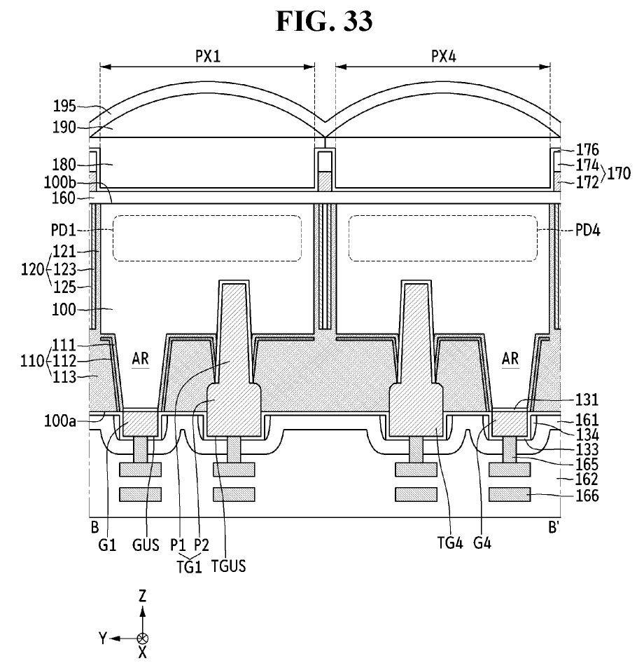

FIGS. 32 and 33 are further cross-sectional views for illustrating an image sensor according to one or more embodiments. For convenience of description, contents duplicate with those as described above with reference to FIGS. 1 to 31 will be briefly described or descriptions thereof will be omitted.

Referring to FIGS. 2, 32, and 33, in the image sensor according to one or more embodiments, the connection pad 140 may be disposed on the first surface 100a of the substrate 100 and between adjacent ones of the first to fourth floating diffusion regions FD1 to FD4. The connection pad 140 may be disposed on the shallow trench isolation pattern 110 and between adjacent ones of the first to fourth floating diffusion regions FD1 to FD4.

In one or more embodiments, the second extension portion E2 may extend into the shallow trench isolation pattern 110. The second extension portion E2 may extend into the first element isolation film 111. For example, the second extension portion E2 may be spaced apart from the first to fourth floating diffusion regions FD1 to FD4. In another example, the first to fourth floating diffusion regions FD1 to FD4 may be in contact with the shallow trench isolation pattern 110, and the second extension portion E2 may be in contact with the first to fourth floating diffusion regions FD1 to FD4.

In one or more embodiments, the uppermost surfaces 150US of the first to fourth pads 151 to 154 may be positioned at a lower vertical level than a vertical level of the uppermost surface 140US of the connection pad 140 in the third direction Z. The uppermost surfaces 150US of the first to fourth pads 151 to 154 are positioned at a lower vertical level than a vertical level of each of the upper surfaces TGUS of the first to fourth transfer gate electrodes TG and the upper surfaces GUS of the first to fourth gate electrodes G1 to G4 in the third direction Z.

The upper surfaces TGUS of the first to fourth transfer gate electrodes TG may be substantially coplanar with the upper surfaces GUS of the first to fourth gate electrodes G1 to G4 and the upper surfaces 140US of the connection pads 140. However, the embodiments are not limited thereto.

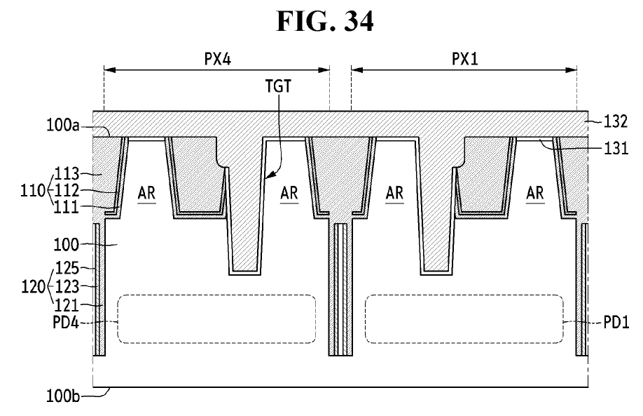

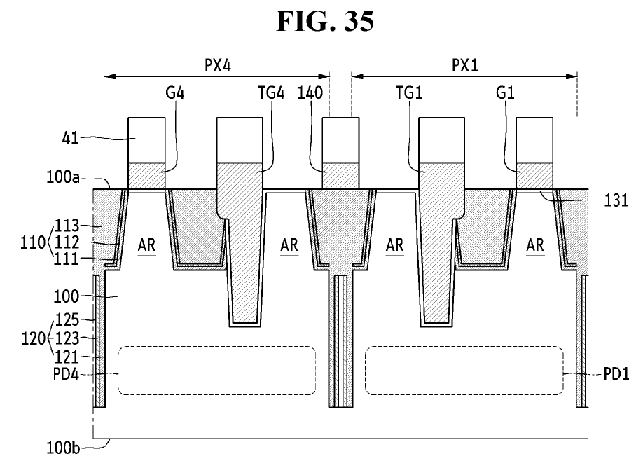

FIGS. 34 and 35 are diagrams illustrating intermediate structures corresponding to intermediate steps of a method for manufacturing an image sensor according to one or more embodiments. For convenience of description, contents duplicate with those as described above with reference to FIGS. 1 to 33 will be briefly described or descriptions thereof will be omitted. FIG. 34 is a diagram of an intermediate structure corresponding to an intermediate step after FIG. 7.

Referring to FIGS. 2 and 34, the gate dielectric film 131 and the preliminary gate electrode film 132 are formed. The gate dielectric film 131 may be formed along the substrate 100 and may not be formed along the shallow trench isolation pattern 110. The preliminary gate electrode film 132 may fill the transfer gate trench TGT.

For example, the preliminary gate electrode film 132 including the polysilicon film into which impurities are implanted may be formed in the step of FIG. 34. In another example, the preliminary gate electrode film 132 including the polysilicon film may be formed in the step of FIG. 34, and the impurities may be implanted thereto by performing an ion implantation process on the first to fourth transfer gate electrodes TG1 to TG4, the first to fourth gate electrodes G1 to G4, and the connection pad 140 as the polysilicon films, in the step of FIG. 35 to be described later.

Referring to FIGS. 2 and 35, the preliminary gate electrode film 132 of FIG. 34 is patterned to form the first to fourth transfer gate electrodes TG1 to TG4, the first to fourth gate electrodes G1 to G4, and the connection pad 140. The connection pad 140 may be formed on the shallow trench isolation pattern 110 and between the first to fourth floating diffusion regions FD1 to FD4.

For example, a mask pattern 41 may be formed on the preliminary gate electrode film 132 of FIG. 34, and the first to fourth transfer gate electrodes TG1 to TG4, the first to fourth gate electrodes G1 to G4, and the connection pad 140 may be formed by performing a chemical mechanical planarization process or an etch-back process on a portion of the preliminary gate electrode film 132 not covered with the mask pattern 41 and exposed. The mask pattern 41 may be removed.

The manufacturing process as above-described with reference to FIGS. 24 to 28 may be performed, and the image sensor as above-described with reference to FIG. 32 may be formed.

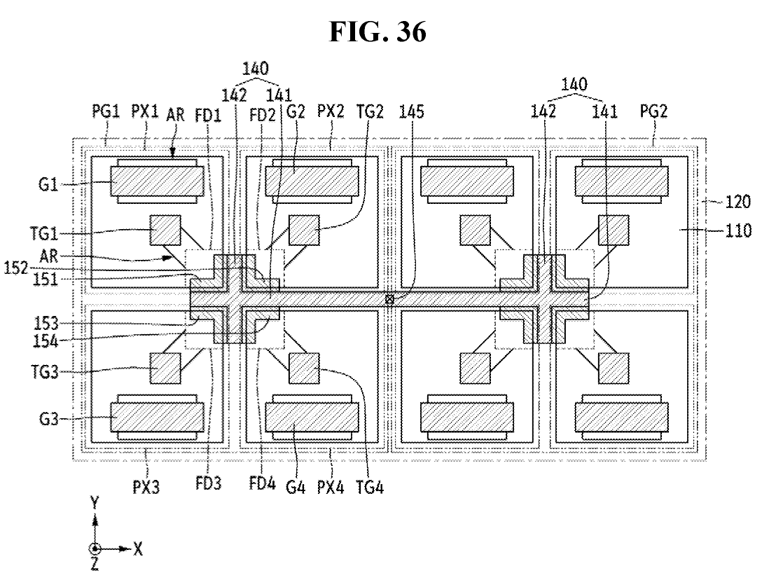

FIGS. 36 to 41 are plan views for illustrating a pixel array of an image sensor according to one or more embodiments. For convenience of description, contents duplicate with those as above-described with reference to FIGS. 1 to 35 will be briefly described or descriptions thereof will be omitted.

Referring to FIGS. 36 to 41, the image sensor according to one or more embodiments may include a first pixel group PG1 and a second pixel group PG2 adjacent to each other. For example, the second pixel group PG2 may be adjacent to the first pixel group PG1 in the first direction X.

Each of the first pixel group PG1 and the second pixel group PG2 may include the first to fourth pixels PX1 to PX4 as described above with reference to FIGS. 2 to 4, the first to fourth pixels PX1 to PX4 as described above with reference to FIGS. 19 and 20, the first to fourth pixels PX1 to PX4 as described above with reference to FIGS. 29 and 30, or the first to fourth pixels PX1 to PX4 as described above with reference to FIGS. 32 and 33.

The connection pad 140 and the first to fourth pads 151 to 154 as described above with reference to FIGS. 2 to 4, the connection pad 140 and the first to fourth pads 151 to 154 as described above with reference to FIGS. 19 and 20, the connection pad 140 and the first to fourth pads 151 to 154 as described above with reference to FIGS. 29 and 30, or the connection pad 140 and the first to fourth pads 151 to 154 as described above with reference to FIGS. 32 and 33 may be formed on each of the first pixel group PG1 and the second pixel group PG2.

The connection pad 140 on the first pixel group PG1 may be connected to the connection pad 140 on the second pixel group PG2. The first extension portion 141 on the first pixel group PG1 and the first extension portion 141 on the second pixel group PG2 may extend in the first direction X and may be directly connected to each other. The second extension portion 142 on the first pixel group PG1 may intersect the first extension portion 141 on the first pixel group PG1. The second extension portion 142 on the second pixel group PG2 may intersect the first extension portion 141 on the second pixel group PG2.

For example, the first contact 145 may be disposed on the connection pad 140 and between the first pixel group PG1 and the second pixel group PG2.

Referring to FIG. 36, in one or more embodiments, the first to fourth pads 151 to 154 may be spaced apart from each other. The first to fourth pads 151 to 154 on the first pixel group PG1 may be connected to each other via the connection pad 140, while the first to fourth pads 151 to 154 on the second pixel group PG2 may be connected to each other via the connection pad 140.

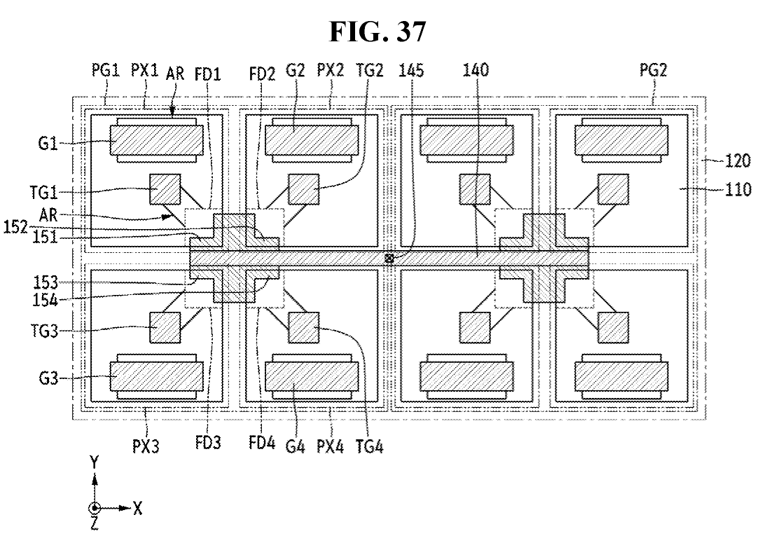

Referring to FIGS. 37 to 41, in one or more embodiments, at least some of the first to fourth pads 151 to 154 may extend along the upper surface of the connection pad 140. At least some of the first to fourth pads 151 to 154 may extend along the upper surface of the connection pad 140 so as to be directly connected to each other. Although it is illustrated that a contact relationship between the first to fourth pads 151 to 154 on the first pixel group PG1 and a contact relationship between the first to fourth pads 151 to 154 on the second pixel group PG2 are identical with each other, embodiments are not limited thereto, and the contact relationship between the first to fourth pads 151 to 154 on the first pixel group PG1 and the contact relationship between the first to fourth pads 151 to 154 on the second pixel group PG2 may be different from each other.

Referring to FIG. 37, in one or more embodiments, the first pad 151 and the second pad 152 adjacent to each other in the first direction X and disposed on each of the first pixel group PG1 and the second pixel group PG2 may be directly connected to each other. The third pad 153 and the fourth pad 154 adjacent to each other in the first direction X and disposed on each of the first pixel group PG1 and the second pixel group PG2 may be directly connected to each other.

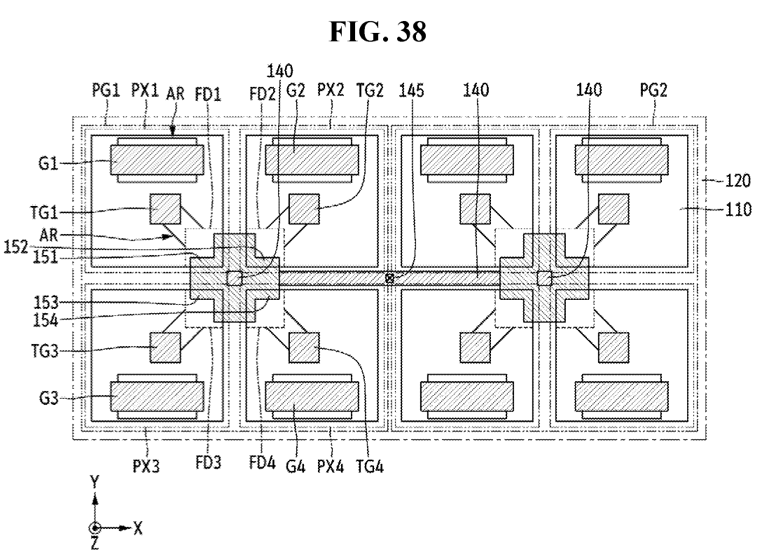

Referring to FIG. 38, in one or more embodiments, the first to fourth pads 151 to 154 on each of the first pixel group PG1 and the second pixel group PG2 may be directly connected to each other. The first to fourth pads 151 to 154 on the first pixel group PG1 may not cover a portion of the upper surface of the connection pad 140 between the first to fourth pads 151 to 154 so as to be exposed.

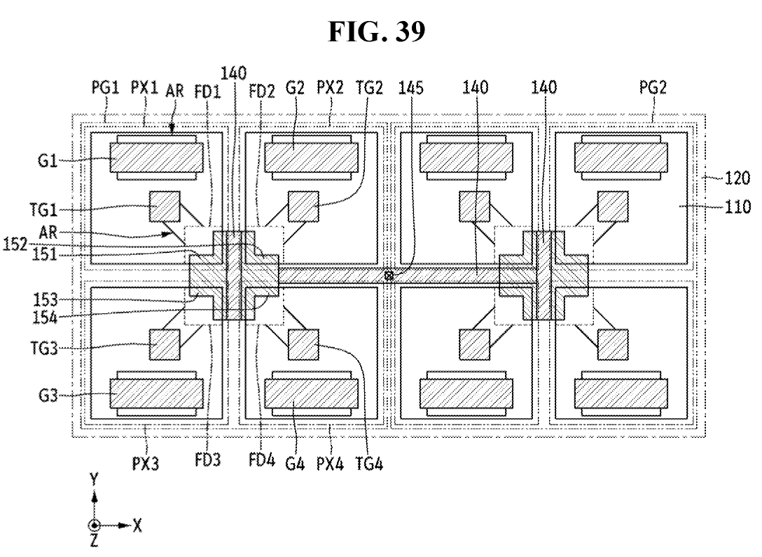

Referring to FIG. 39, in one or more embodiments, the first pad 151 and the third pad 153 adjacent to each other in the second direction Y and disposed on each of the first pixel group PG1 and the second pixel group PG2 may be directly connected to each other. The second pad 152 and the fourth pad 154 adjacent to each other in the second direction Y and disposed on each of the first pixel group PG1 and the second pixel group PG2 may be directly connected to each other.

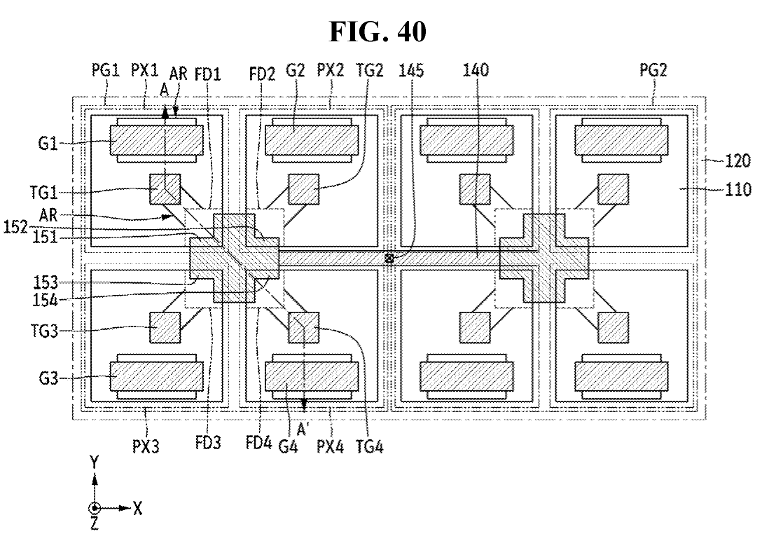

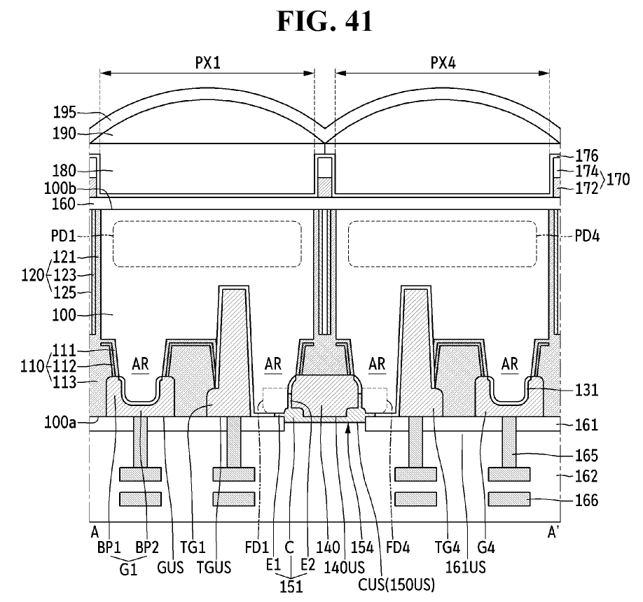

Referring to FIGS. 40 and 41, in one or more embodiments, the first to fourth pads 151 to 154 on each of the first pixel group PG1 and the second pixel group PG2 may extend along an entire upper surface of the connection pad 140 and may be directly connected to each other. The upper surface of the connection pad 140 may be covered with the first to fourth pads 151 to 154 on each of the first pixel group PG1 and the second pixel group PG2.

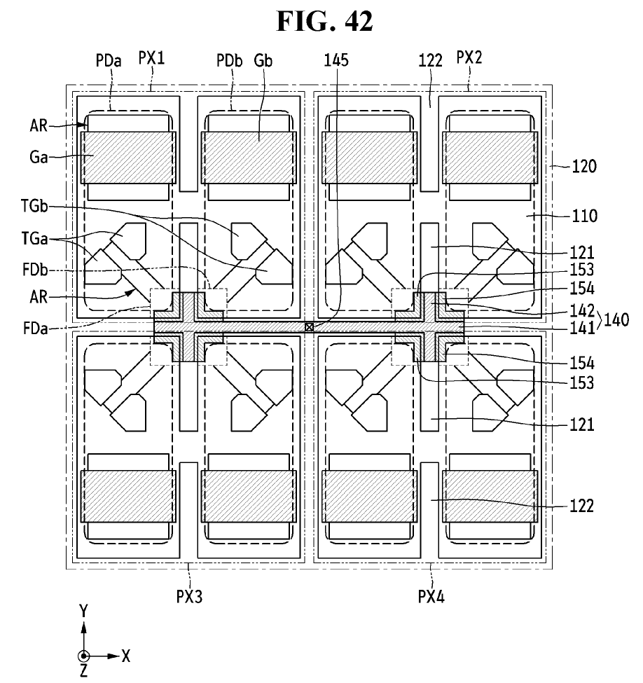

FIG. 42 is a plan view for illustrating a pixel array of an image sensor according to one or more embodiments.

Referring to FIG. 42, in the image sensor according to one or more embodiments, each of the first to fourth pixels PX1 to PX4 may include a plurality of photodiodes PDa and PDb and a plurality of floating diffusion regions FDa and FDb.

For example, the photodiodes PDa and PDb in each of the first to fourth pixels PX1 to PX4 may be adjacent to each other in the first direction X or the second direction Y.

The PD isolation pattern 120 may include a first isolation pattern 120a and a second isolation pattern 120b. The first isolation pattern 120a and the second isolation pattern 120b may be interposed between a photodiode PDa and a photodiode PDb of each of the first to fourth pixels PX1 to PX4. For example, the first isolation pattern 120a and the second isolation pattern 120b may extend in the second direction Y so as to isolate the photodiode PDa and the photodiode PDb of each of the first to fourth pixels PX1 to PX4 from each other. For example, the first isolation pattern 120a may be adjacent to the floating diffusion region FDa and FDb, and the first isolation pattern 120a and the second isolation pattern 120b may be spaced apart from each other in the second direction Y.

The transfer gate electrode TGa may be disposed in the active area AR adjacent to the photodiode PDa, and the transfer gate electrode TGb may be disposed in the active area AR adjacent to the photodiode PDb.

In one or more embodiments, a plurality of transfer gate electrodes TGa may be disposed in the active area AR adjacent to the floating diffusion region FDa, and a plurality of transfer gate electrodes TGb may be disposed in the active area AR adjacent to the floating diffusion region FDb. The number and arrangement of the transfer gate electrodes TGa and TGb are only examples, and are not limited to those as shown.

Each of the first to fourth pixels PX1 to PX4 may include a plurality of gate electrodes Ga and Gb. The number and arrangement of the gate electrodes Ga and Gb in each of the first to fourth pixels PX1 to PX4 are examples, and embodiments are not limited to those as illustrated.

The connection pad 140 and the first to fourth pads 151 to 154 as described above with reference to FIGS. 2 to 4, the connection pad 140 and the first to fourth pads 151 to 154 as described above with reference to FIGS. 19 and 20, the connection pad 140 and the first to fourth pads 151 to 154 as described above with reference to FIGS. 29 and 30, or the connection pad 140 and the first to fourth pads 151 to 154 as described above with reference to FIGS. 32 and 33 may be formed on a combination of the first pixel PX1 and the third pixel PX3. The connection pad 140 and the first to fourth pads 151 to 154 as described above with reference to FIGS. 2 to 4, the connection pad 140 and the first to fourth pads 151 to 154 as described above with reference to FIGS. 19 and 20, the connection pad 140 and the first to fourth pads 151 to 154 as described above with reference to FIGS. 29 and 30, or the connection pad 140 and the first to fourth pads 151 to 154 as described above with reference to FIGS. 32 and 33 may be formed on a combination of the second pixel PX2 and the fourth pixel PX4.

The second extension portion 142 on the combination of the first pixel PX1 and the third pixel PX3 may intersect the first extension portion 141 on the combination of the first pixel PX1 and the third pixel PX3. The second extension portion 142 on the combination of the second pixel PX2 and the fourth pixel PX4 may intersect the first extension portion 141 on the combination of the second pixel PX2 and the fourth pixel PX4. The connection pad 140 on the combination of the first pixel PX1 and the third pixel PX3 may be connected to the connection pad 140 on the combination of the second pixel PX2 and the fourth pixel PX4. The first extension portion 141 on the combination of the first pixel PX1 and the third pixel PX3 and the first extension portion 141 on the combination of the second pixel PX2 and the fourth pixel PX4 may extend in the first direction X and may be directly connected to each other.

For example, the first contact 145 may be disposed on the connection pad 140 and between the first to fourth pixels PX1 to PX4.

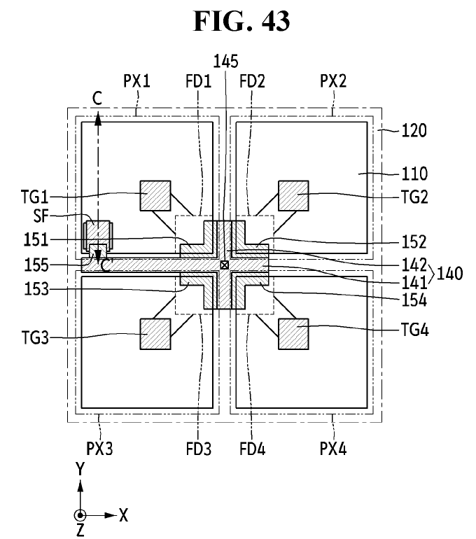

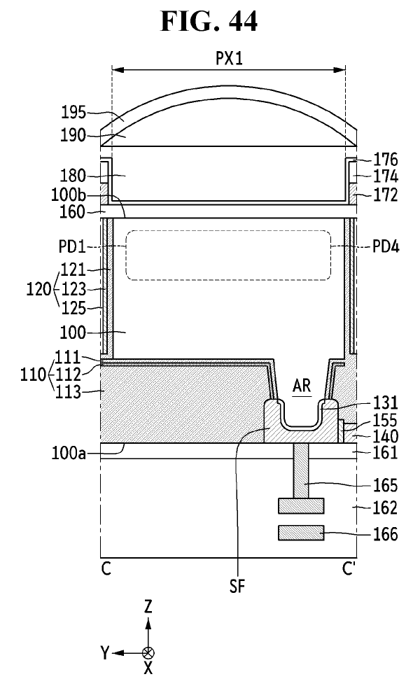

FIG. 43 is a plan view for illustrating a pixel array of an image sensor according to one or more embodiments. FIG. 44 is a schematic cross-sectional view taken along a line C-C' of FIG. 43. For convenience of description, contents duplicate with those as above-described with reference to FIGS. 1 to 42 will be briefly described or descriptions thereof will be omitted.

Referring to FIGS. 43 and 44, in the image sensor according to one or more embodiments, the connection pad 140 and the first to fourth pads 151 to 154 may electrically connect the source follower gate electrode SF and the first to fourth floating diffusion regions FD1 to FD4 to each other. The source follower transistor SF may be provided as a gate electrode of the source follower transistor SF of FIG. 1. The number and arrangement of the source follower transistors SF are examples, and are not limited to what are shown.

For example, the first pixel PX1 may include a source follower gate electrode SF. A fifth pad 155 may be disposed between the source follower gate electrode SF and the connection pad 140. The fifth pad 155 may be in contact with the source follower gate electrode SF and the connection pad 140. The first extension portion 141 may extend along the first direction X and on the shallow trench isolation pattern 110. The fifth pad 155 may be in contact with the first extension portion 141. For example, the fifth pad 155 may be spaced apart from the first pad 151.

For example, the source follower gate electrode SF may be formed in the substrate 100. In another example, the source follower gate electrode SF may be formed on the first surface 100a of the substrate 100 like the first gate electrode G1 of FIG. 19.

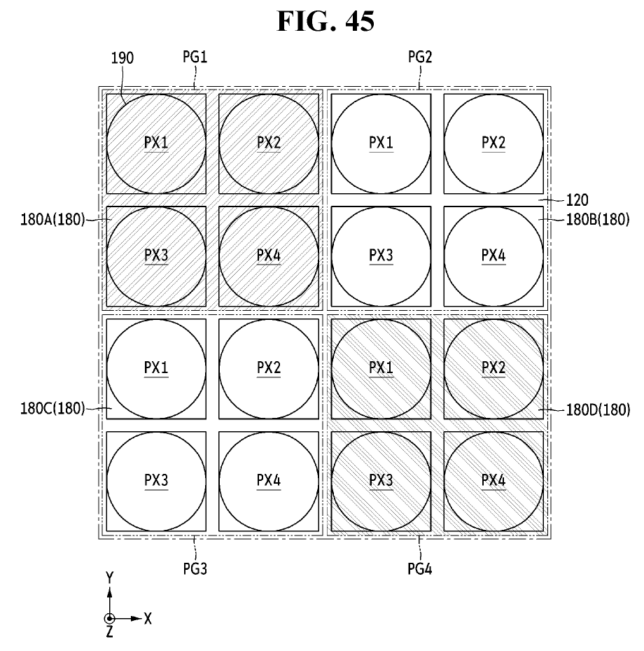

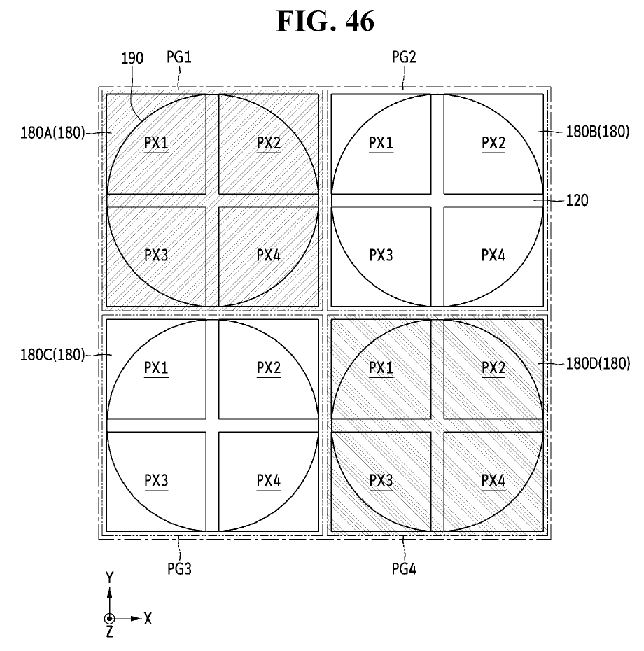

FIGS. 45 and 46 are various plan views for illustrating a pixel array of an image sensor according to one or more embodiments. For convenience of description, contents duplicate with those as above-described with reference to FIGS. 1 to 44 will be briefly described or descriptions thereof will be omitted.

Referring to FIGS. 45 and 46, the image sensor according to one or more embodiments may include first to fourth pixel groups PG1 to PG4 adjacent to each other.

The second pixel group PG2 may be adjacent to the first pixel group PG1 in the first direction X. The third pixel group PG3 may be adjacent to the first pixel group PG1 in the second direction Y. The fourth pixel group PG4 may be adjacent to the second pixel group PG2 in the second direction Y, and may be adjacent to the third pixel group PG3 in the first direction X. That is, the fourth pixel group PG4 may be adjacent to the first pixel group PG1 in a diagonal direction between the first direction X and the second direction Y.

Each of the first to fourth pixel groups PG1 to PG4 may correspond to the pixel group PG as described above with reference to FIG. 1. Each of the first to fourth pixel groups PG1 to PG4 may include the first to fourth pixels PX1 to PX4 as described above with reference to FIG. 1.

In one or more embodiments, pixels included in each pixel group may share a color filter of the same color. In addition, adjacent pixel groups may have color filters of different colors. For example, the first to fourth pixel groups PG1 to PG4 may include color filters 180 arranged in a Bayer pattern. For example, the pixels PX1 to PX4 of the first pixel group PG1 may overlap a red color filter 180A, and the pixels PX1 to PX4 of the fourth pixel group PG4 may overlap a blue color filter 180D. The pixels PX1 to PX4 of the second pixel group PG2 and the pixels PX1 to PX4 of the third pixel group PG3 may overlap green color filters 180B and 180C, respectively.

Referring to FIG. 46, in the image sensor according to one or more embodiments, the unit pixels included in each pixel group may share one microlens 190 with each other.

For example, the microlenses 190 may be arranged in a corresponding manner to the first to fourth pixel groups PG1 to PG4. The microlens 190 may cover the first to fourth pixels PX1 to PX4 of each of the first to fourth pixel groups PG1 to PG4. Accordingly, each of the first to fourth pixel groups PG1 to PG4 may provide an AF (auto-focus) function. For example, the first pixel group PG1 may provide a phase detection AF (PDAF) function using the photodiodes PD1 to PD4.

While embodiments have been described with reference to the figures, it will be understood by those of ordinary skill in the art that various changes in form and details may be made therein without departing from the spirit and scope as defined by the following claims and their equivalents.

What is claimed is:

1. An image sensor comprising:
a substrate;
a first pixel comprising a first floating diffusion region in the substrate;
a second pixel comprising a second floating diffusion region in the substrate;
a first pad comprising:
a first extension portion extending along a first surface of the first floating diffusion region and contacting the first floating diffusion region;
a second extension portion extending into the substrate; and
a first connection portion connecting the first extension portion and the second extension portion to each other;
a second pad comprising:
a third extension portion extending along a first surface of the second floating diffusion region and contacting the second floating diffusion region;
a fourth extension portion extending into the substrate; and
a second connection portion connecting the third extension portion and the fourth extension portion to each other; and
a connection pad between the first pad and the second pad and in contact with the first pad and the second pad.

2. The image sensor of claim 1, wherein a level of a first surface of the first connection portion and a level of a first surface of the second connection portion are greater than a level of a first surface of the first extension portion and a level of a first surface of the third extension portion in a vertical direction.

3. The image sensor of claim 1, wherein the connection pad is in the substrate and between the first floating diffusion region and the second floating diffusion region,
wherein a level of a first surface of the first connection portion and a level of a first surface of the second connection portion are greater than a level of a first surface of the connection pad in a vertical direction.

4. The image sensor of claim 1, wherein the second extension portion contacts the first floating diffusion region and the connection pad, and
wherein the fourth extension portion contacts the second floating diffusion region and the connection pad.

5. The image sensor of claim 1, further comprising a gate electrode in the substrate,
wherein a level of a first surface of the first connection portion and a level of a first surface of the second connection portion is greater than a level of a first surface of the gate electrode in a vertical direction.

6. The image sensor of claim 1, further comprising a transfer gate electrode comprising a first portion in the substrate and a second portion disposed on the substrate,
wherein a level of a first surface of the first connection portion and a level of a first surface of the second connection portion is less than a level of a first surface of the transfer gate electrode in a vertical direction.

7. The image sensor of claim 1, further comprising a gate electrode on the substrate,
wherein a level of a first surface of the first connection portion and a level of a first surface of the second connection portion is less than a level of a first surface of the gate electrode in a vertical direction.

8. The image sensor of claim 1, further comprising:
a gate electrode in the substrate; and
a third pad in contact with the gate electrode and the connection pad.

9. The image sensor of claim 1, wherein the connection pad is on the substrate and between the first floating diffusion region and the second floating diffusion region, and
wherein a level of a first surface of the first connection portion and a level of a first surface of the second connection portion is less than a level of a first surface of the connection pad in a vertical direction.

10. The image sensor of claim 9, further comprising an element isolation pattern defining an active area in the substrate,
wherein the second extension portion extends into the element isolation pattern adjacent to the first floating diffusion region,
wherein the fourth extension portion extends into the element isolation pattern adjacent to the second floating diffusion region.

11. The image sensor of claim 1, further comprising an insulating film on the substrate and a first surface of the connection pad, and exposing a first surface of the first connection portion and a first surface of the second connection portion,
wherein a level of a first surface of the first connection portion and a level of a first surface of the second connection portion is less than a level of a first surface of the insulating film in a vertical direction.

12. The image sensor of claim 1, wherein the first pad and the second pad are spaced apart from each other.

13. The image sensor of claim 1, wherein the first pad and the second pad extend along a first surface of the connection pad, the first pad and the second pad being connected to each other.

14. The image sensor of claim 1, wherein each of the first pixel and the second pixel comprises a photodiode in the substrate.

15. An image sensor comprising:
a substrate;
a first floating diffusion region, a second floating diffusion region, a third floating diffusion region, and a fourth floating diffusion region in the substrate;
a first pad in contact with a first surface of the first floating diffusion region;
a second pad in contact with a first surface of the second floating diffusion region;
a third pad in contact with a first surface of the third floating diffusion region;
a fourth pad in contact with a first surface of the fourth floating diffusion region; and
a connection pad in contact with the first pad, the second pad, the third pad, and the fourth pad,
wherein a level of an uppermost surface of the first pad, a level of an uppermost surface of the second pad, a level of an uppermost surface of the third pad, and a level of an uppermost surface of the fourth pad are different from a level of a first surface of the connection pad in a vertical direction.

16. The image sensor of claim 15, wherein the first pad, the second pad, the third pad, and the fourth pad are spaced apart from each other.

17. The image sensor of claim 15, wherein the first pad and the second pad are connected to each other,
wherein the third pad and the fourth pad are connected to each other,
wherein the first pad and the second pad are spaced apart from each other, and the third pad and the fourth pad are spaced apart from each other.

18. The image sensor of claim 15, wherein the first pad, the second pad, the third pad, and the fourth pad are connected to each other.

19. An image sensor comprising:
a substrate;
a first floating diffusion region, a second floating diffusion region, a third floating diffusion region, and a fourth floating diffusion region in the substrate;
a first pad in contact with the first floating diffusion region;
a second pad in contact with the second floating diffusion region;
a third pad in contact with the third floating diffusion region;
a fourth pad in contact with the fourth floating diffusion region;
a connection pad contacting the first pad, the second pad, the third pad, and the fourth pad;
a contact on the connection pad; and
a transfer gate electrode at least partially in the substrate,
wherein a level of an uppermost surface of the first pad, a level of an uppermost surface of the second pad, a level of an uppermost surface of the third pad, and a level of an uppermost surface of the fourth pad are different from a level of an upper surface of the connection pad and a level of a first surface of the transfer gate electrode in a vertical direction.

20. The image sensor of claim 19, wherein the connection pad is in the substrate, and
wherein the image sensor further comprises a gate dielectric film between the connection pad and the substrate and between the transfer gate electrode and the substrate.
